(19) United States
(12) Patent Application Publication
(10) Pub. No.: US 2024/0176233 A1
(43) Pub. Date: May 30, 2024

(54) PHOTOSENSITIVE RESIN COMPOSITION, PHOTOSENSITIVE RESIN LAYER USING THE SAME AND COLOR FILTER

(71) Applicant: SAMSUNG SDI CO., LTD., Yongin-si (KR)

(72) Inventors: Chang-Hyun KWON, Suwon-si (KR); Heejo MOON, Suwon-si (KR); Juho JUNG, Suwon-si (KR); Kwangwon SEO, Suwon-si (KR); Baek Soung PARK, Suwon-si (KR)

(21) Appl. No.: 18/379,933

(22) Filed: Oct. 13, 2023

(30) Foreign Application Priority Data
Nov. 2, 2022 (KR) 10-2022-0144733

(51) Int. Cl. G03F 7/00; G02F 1/1335; G03F 7/004; G03F 7/028; G03F 7/029; G03F 7/038

(52) U.S. Cl. CPC G03F 7/0007; G02F 1/133514; G03F 7/0048; G03F 7/028; G03F 7/029; G03F 7/0382

(57) ABSTRACT

A photosensitive resin composition, a photosensitive resin layer manufactured using the same, and a color filter, the photosensitive resin composition includes a colorant; a photopolymerizable compound; a photopolymerization initiator; a binder resin; and a solvent, wherein the colorant includes a pigment, a dispersant, and a dispersing aid represented by Chemical Formula 1,

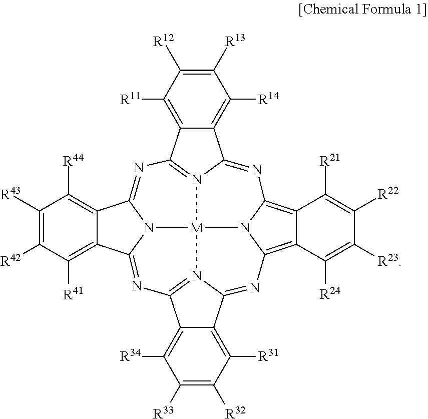

### CROSS-REFERENCE TO RELATED APPLICATION

This application claims priority to and the benefit of Korean Patent Application No. 10-2022-0144733 filed in the Korean Intellectual Property Office on Nov. 2, 2022, the entire contents of which are incorporated herein by reference.

### BACKGROUND

### 1. Field

Embodiments relate to a photosensitive resin composition, a photosensitive resin layer manufactured using the same, and a color filter.

### 2. Description of the Related Art

A liquid crystal display device is a type of display that has an advantage of lightness, thinness, low cost, low power consumption for operation, and improved adherence to an integrated circuit and has been more widely used for a laptop computer, a monitor, and a TV screen.

The liquid crystal display device may include a lower substrate on which a black matrix, a color filter, and an ITO pixel electrode are formed, and an upper substrate on which an active circuit portion including a liquid crystal layer, a thin film transistor, and a capacitor layer and an ITO pixel electrode are formed.

The color filter may be formed in a pixel region by sequentially stacking a plurality of color filters (e.g., formed of three primary colors (red (R), green (G), and blue (B)) in a predetermined order to form each pixel, and a black matrix layer may be disposed in a predetermined pattern on a transparent substrate to form a boundary between the pixels.

The pigment dispersion method is a method of forming a color filter and provides a colored thin layer (photosensitive resin layer) by repeating a series of processes such as coating a photopolymerizable composition including a colorant on a transparent substrate including a black matrix, exposing a formed pattern to light, removing a non-exposed part with a solvent, and thermally curing the same.

The photosensitive resin composition (pigment-type photosensitive resin composition) used in the production of color filters according to the pigment dispersion method may include an alkali soluble resin, a photopolymerization monomer, a photopolymerization initiator, an epoxy resin, a solvent, and other additives. The pigment dispersion method having the above characteristics may be applied to manufacturing LCDs such as mobile phones, laptop computers, monitors, and TVs.

### SUMMARY

The embodiments may be realized by providing a photosensitive resin composition including a colorant; a photopolymerizable compound; a photopolymerization initiator; a binder resin; and a solvent, wherein the colorant includes a pigment, a dispersant, and a dispersing aid represented by Chemical Formula 1,

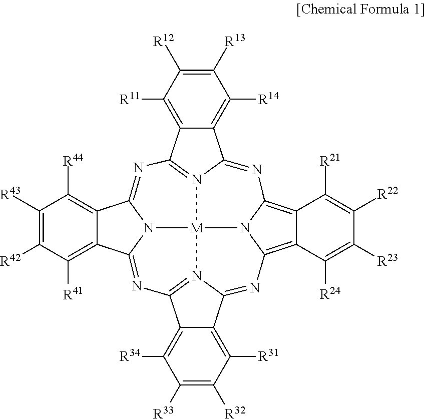

in Chemical Formula 1, M is Cu or Zn; R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group; and R⁴¹ to R⁴⁴ are each independently a hydrogen atom, a halogen atom, a hydroxy group, a substituted or unsubstituted C1 to C20 alkyl group, or a substituted or unsubstituted C1 to C20 alkoxy group, provided that at least one of R⁴¹ to R⁴⁴ is a C1 to C20 alkoxy group substituted with a sulfonate group.

The embodiments may be realized by providing a photosensitive resin layer manufactured using the photosensitive resin composition according to an embodiment.

The embodiments may be realized by providing a color filter comprising the photosensitive resin layer according to an embodiment.

The embodiments may be realized by providing a display device comprising the color filter according to an embodiment.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B.

As used herein, when specific definition is not otherwise provided, “substituted” refers to replacement of at least one hydrogen atom of a compound by a substituent of a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, when specific definition is not otherwise provided, a “heterocycloalkyl group”, a “heterocycloalkenyl group”, a “heterocycloalkynyl group,” and a “heterocycloalkylene group” refer to each cyclic compound of cycloalkyl, cycloalkenyl, cycloalkynyl, and cycloalkylene including at least one heteroatom of N, O, S, or P.

As used herein, when specific definition is not otherwise provided, “(meth)acrylate” refers to both “acrylate” and “methacrylate”.

As used herein, when specific definition is not otherwise provided, the term “combination” refers to mixing or copolymerization. Further, “copolymerization” means block copolymerization or random copolymerization, and “copolymer” means block copolymer or random copolymer.

As used herein, when a definition is not otherwise provided, hydrogen is bonded at the position when a chemical bond is not drawn where supposed to be given.

As used herein, when specific definition is not otherwise provided, “*” refers to a linking point with the same or different atom or chemical formula.

As used herein, when specific definition is not otherwise provided, “particle diameter” may mean a diameter of a particle, and the particle diameter may be a “Z-average” value of particle diameters measured through a dynamic light scattering method.

(Photosensitive Resin Composition)

An embodiment may provide a photosensitive resin composition including, e.g., (A) a colorant; (B) a photopolymerizable compound; (C) a photopolymerization initiator; (D) a binder resin; and (E) a solvent. In an implementation, the colorant may include, e.g., a pigment, a dispersant, and a dispersing aid represented by Chemical Formula 1.

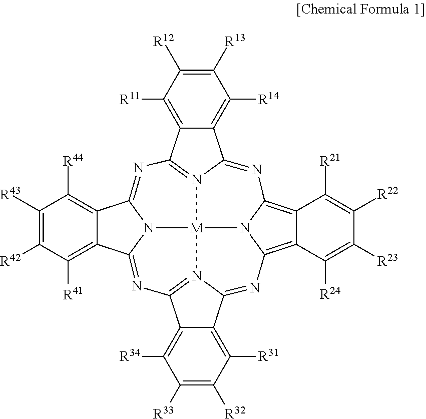

In Chemical Formula 1, M may be, e.g., Cu or Zn. R¹¹ to R¹⁴, R²¹ to R²⁴, and R³¹ to R³⁴ may each independently be or include, e.g., a hydrogen atom, a halogen atom, a hydroxy group, or a substituted or unsubstituted C1 to C20 alkyl group. R⁴¹ to R⁴⁴ may each independently be or include, e.g., a hydrogen atom, a halogen atom, a hydroxy group, a substituted or unsubstituted C1 to C20 alkyl group, or a substituted or unsubstituted C1 to C20 alkoxy group. In an implementation, at least one of R⁴¹ to R⁴⁴ may be, e.g., a C1 to C20 alkoxy group substituted with a sulfonate group.

(A) Colorant

The photosensitive resin composition of an embodiment may be a pigment-type photosensitive resin composition, and the colorant may include a pigment. In a color filter made of a pigment-type photosensitive resin composition, there could be limitations in luminance and contrast ratio due to the size of pigment particles.

In an implementation, in order to be applied for an image sensor, a resin composition composed of smaller particles may be used for forming a fine pattern. In order to achieve this, a compound may be included to facilitate the dispersion of the pigment and that helps prevent re-agglomeration and a composition using the same.

The dispersing aid represented by Chemical Formula 1 may have a sulfonate group asymmetrically substituted with respect to a phthalocyanine mother moiety.

The phthalocyanine mother moiety may interact with the pigment, and a sulfonate group asymmetrically substituted with respect to the phthalocyanine mother moiety may interact with the dispersant or dispersion resin. Accordingly, the dispersing aid represented by Chemical Formula 1 may help enhance the dispersibility and dispersion stability of the pigment by helping the dispersant in the photosensitive resin composition.

In an implementation, the phthalocyanine mother moiety may express a blue color. Accordingly, the dispersing aid represented by Chemical Formula 1 may help increase the coloring power by helping the colorant in the photosensitive resin composition.

In an implementation, the dispersing aid represented by Chemical Formula 1 may be a dispersing aid that helps the dispersant to increase the dispersibility and dispersion stability of the pigment, and help increase the coloring power by helping the colorant. Accordingly, when the photosensitive resin composition including the dispersing aid represented by Chemical Formula 1 is implemented as a color filter and a display device, further improved coloring power (color gamut) and contrast ratio may be exhibited.

In an implementation, R¹¹ to R¹⁴ may each independently be, e.g., a hydrogen atom, a halogen atom, a hydroxyl group, or a substituted or unsubstituted C1 to C20 alkyl group.

In an implementation, R¹¹ to R¹⁴ may be, e.g., all hydrogen atoms or all halogen atoms. In an implementation, the halogen atom may be, e.g., a chlorine atom.

In an implementation, R²¹ to R²⁴ may each independently be, e.g., a hydrogen atom, a halogen atom, a hydroxyl group, or a substituted or unsubstituted C1 to C20 alkyl group.

In an implementation, all of R²¹ to R²⁴ may be hydrogen atoms. In an implementation, one of R²¹ to R²⁴ may be, e.g., a substituted or unsubstituted C1 to C20 alkyl group, and the others may be all hydrogen atoms. In an implementation, one or two of R²¹ to R²⁴ may be, e.g., a branched C4 alkyl group (tert-butyl group), and the others may be all hydrogen atoms.

Compared to the case where all of R²¹ to R²⁴ are hydrogen atoms, when one or both of R²¹ to R²⁴ are branched C4 alkyl groups (tert-butyl groups), solubility of the dispersing aid represented by Chemical Formula 1 in the solvent may be improved.

In an implementation, the dispersing aid represented by Chemical Formula 1 may have sufficient solubility in the solvent due to the presence of A (e.g., an anion of SO₃⁻ alone, or a salt of a combination of SO₃⁻ and Na⁺), and all of R²¹ to R²⁴ may be hydrogen atoms.

In an implementation, R³¹ to R³⁴ may each independently be, e.g., a hydrogen atom, a halogen atom, a hydroxyl group, or a substituted or unsubstituted C1 to C20 alkyl group.

In an implementation, R³¹ to R³⁴ may be all hydrogen atoms.

The sulfonate group asymmetrically substituted with respect to the phthalocyanine mother moiety may be, e.g., a moiety represented by *—O-L¹-L²-A. In an implementation, A may be, e.g., an anion of SO₃⁻ alone, or a salt of a combination of SO₃⁻ and Na⁺. In an implementation, at least one sulfonate group may be asymmetrically substituted with respect to the phthalocyanine mother moiety. A detailed description of this is as follows.

In an implementation, R⁴¹ to R⁴⁴ may each independently be, e.g., a hydrogen atom, a halogen atom, a hydroxyl group, a substituted or unsubstituted C1 to C20 alkyl group, or a moiety represented by *—O-L¹-L²-A. In an implementation, at least one of R⁴¹ to R⁴⁴ may be a moiety represented by *—O-L¹-L²-A.

In an implementation, one of R⁴¹ to R⁴⁴ may be a moiety represented by *—O-L¹-L²-A; and the others may be all hydrogen atoms or all halogen atoms. In an implementation, L¹ may be, e.g., a single bond or a substituted or unsubstituted C6 to C20 arylene group; L² may be, e.g., a single bond or a substituted or unsubstituted C1 to C20 alkylene group; and A may be, e.g., an anion of SO₃⁻ alone, or a salt of a combination of SO₃⁻ and Na⁺.

In an implementation, L¹ may be, e.g., a substituted or unsubstituted phenylene group. In an implementation, L² may be a substituted or unsubstituted C1 to C10 alkylene group. In an implementation, A may be a salt of a combination of SO₃⁻ and Na⁺.

In an implementation, the moiety represented by *—O-L-L²-A may be represented by, e.g., Chemical Formula 2 or Chemical Formula 3.

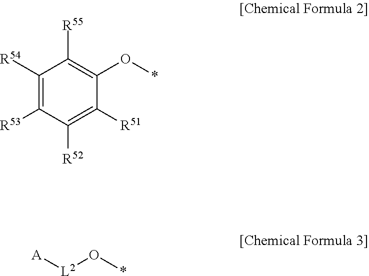

In Chemical Formulae 2 and 3, R⁵¹ to R⁵⁵ may each independently be, e.g., a hydrogen atom, a halogen atom, a hydroxyl group, a substituted or unsubstituted C1 to C20 alkyl group, or a moiety represented by *-L²-A. In an implementation, at least one of R⁵¹ to R⁵⁵ may be moiety represented by *-L²-A. L² may be, e.g., a substituted or unsubstituted C1 to C20 alkylene group. A may be, e.g., an anion of SO₃⁻ alone, or a salt of a combination of SO₃⁻ and Na⁺.

In an implementation, the dispersing aid represented by Chemical Formula 1 may be represented by, e.g., one of Chemical Formulae 1-1 to 1-4:

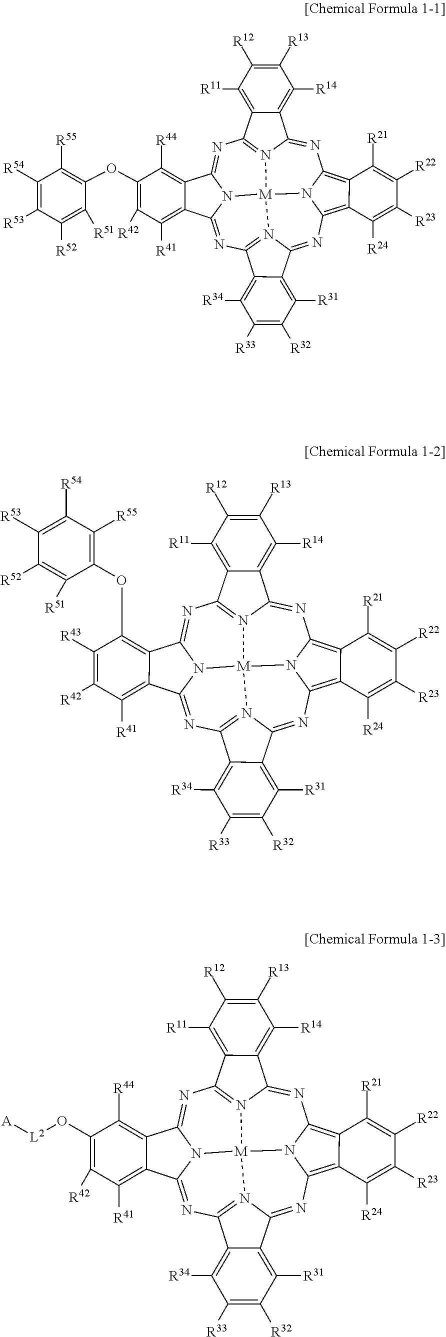

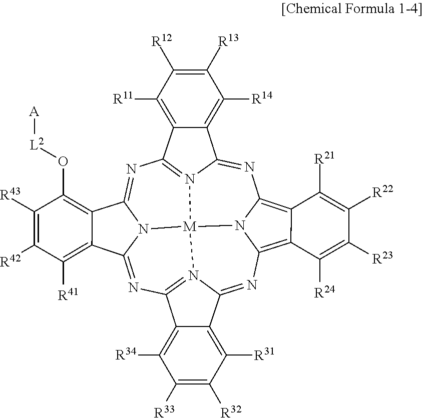

In Chemical Formulae 1-1 to 1-4, M may be, e.g., Cu or Zn. R¹¹ to R¹⁴, R²¹ to R²⁴, R³¹ to R³⁴, and R⁴¹ to R⁴⁴ may each independently be, e.g., a hydrogen atom, a halogen atom, a hydroxy group, or a substituted or unsubstituted C1 to C20 alkyl group. R⁵¹ to R⁵⁵ may each independently be, e.g., a hydrogen atom, a halogen atom, a hydroxyl group, a substituted or unsubstituted C1 to C20 alkyl group, or a moiety represented by *-L²-A. In an implementation, at least one of R⁵¹ to R⁵⁵ may be a moiety represented by *-L²-A. L² may be, e.g., a substituted or unsubstituted C1 to C20 alkylene group. A may be, e.g., an anion of SO₃⁻ alone, or a salt of a combination of SO₃⁻ and Na⁺.

In Chemical Formulas 1-1 to 1-4, detailed descriptions of each substituent may be as described above.

In an implementation, the dispersing aid represented by Chemical Formula 1 may be, e.g., one of the following compounds.

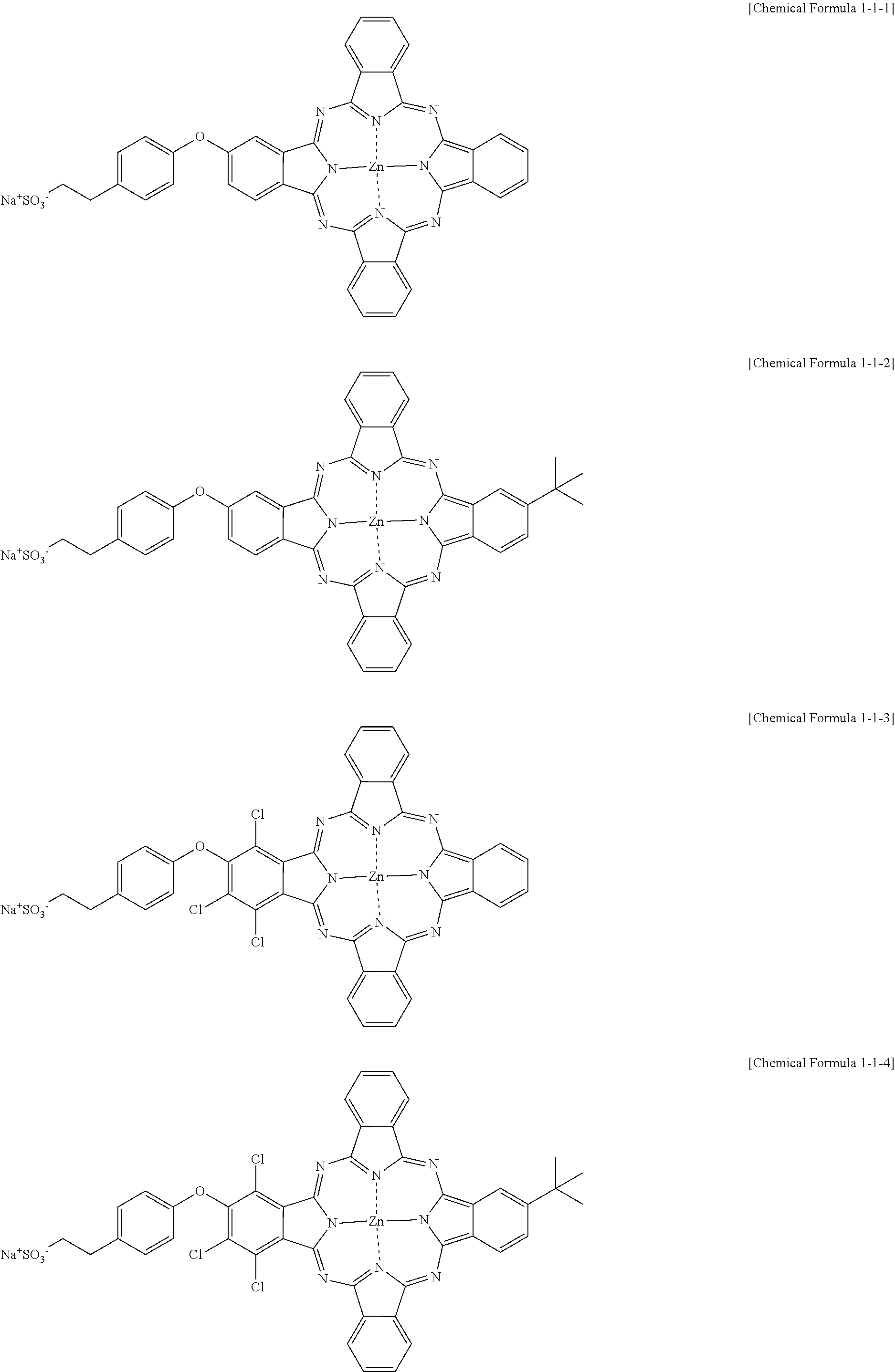

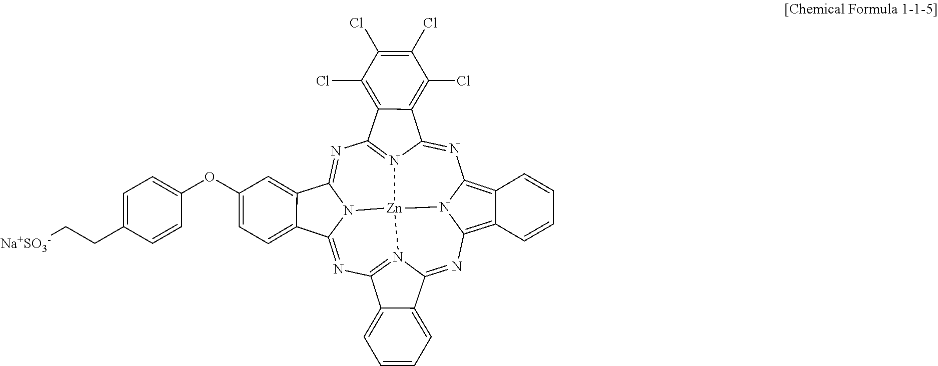

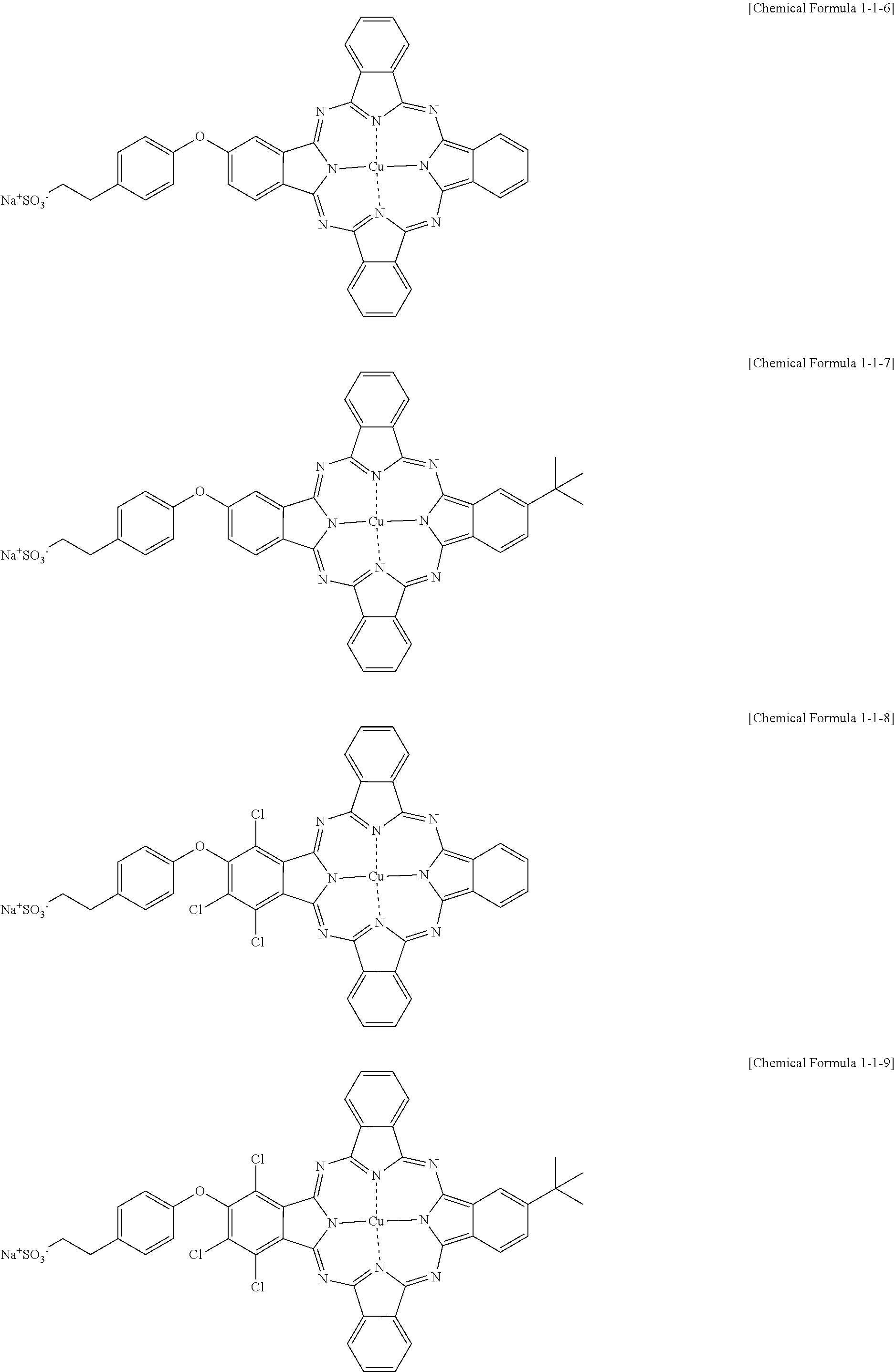

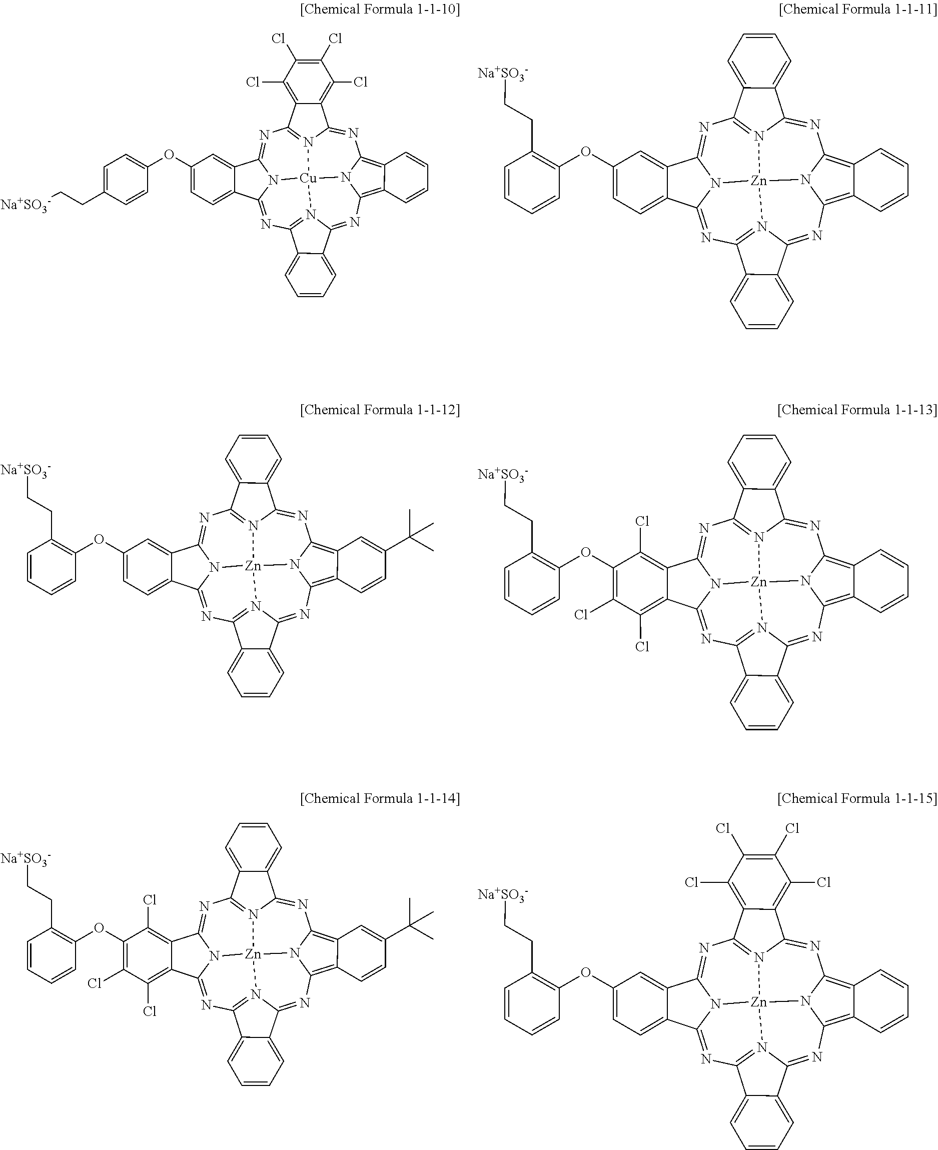

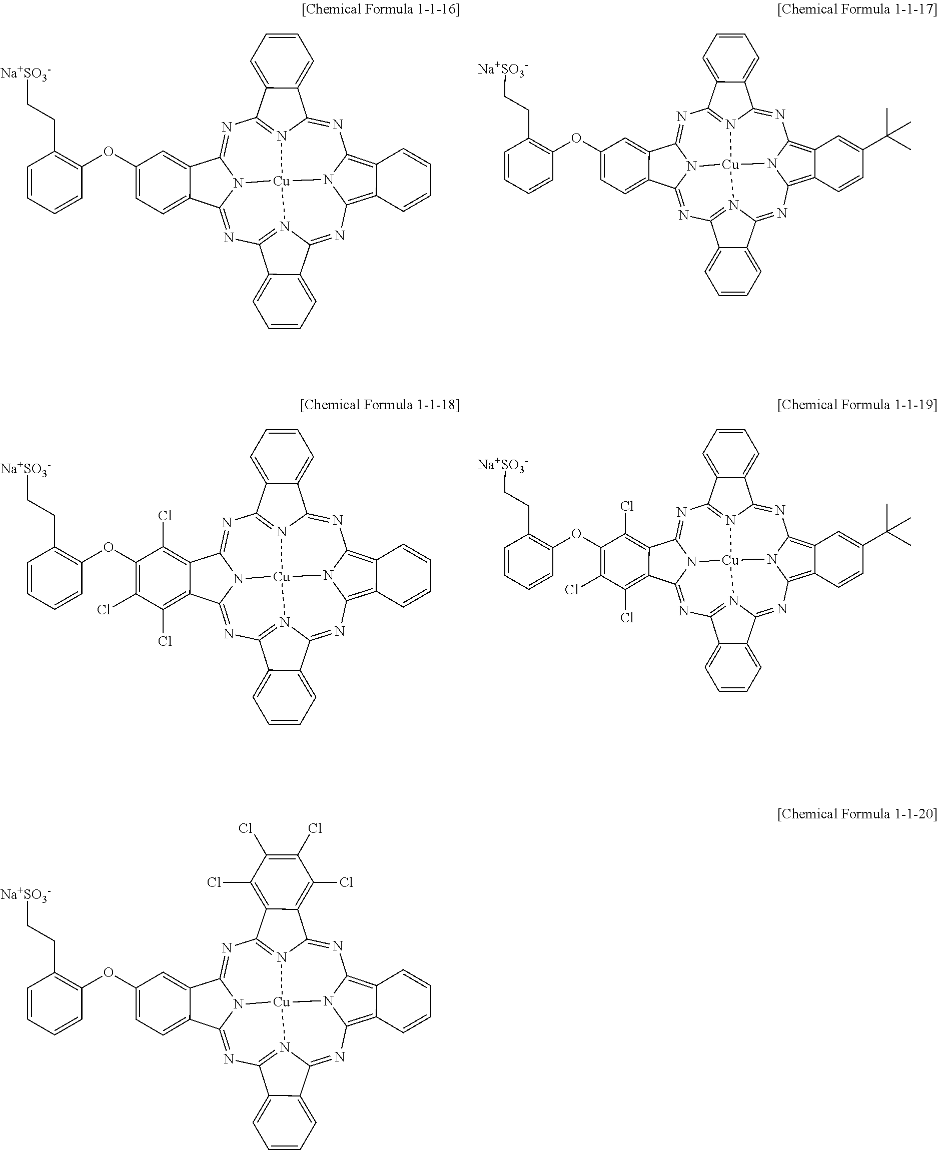

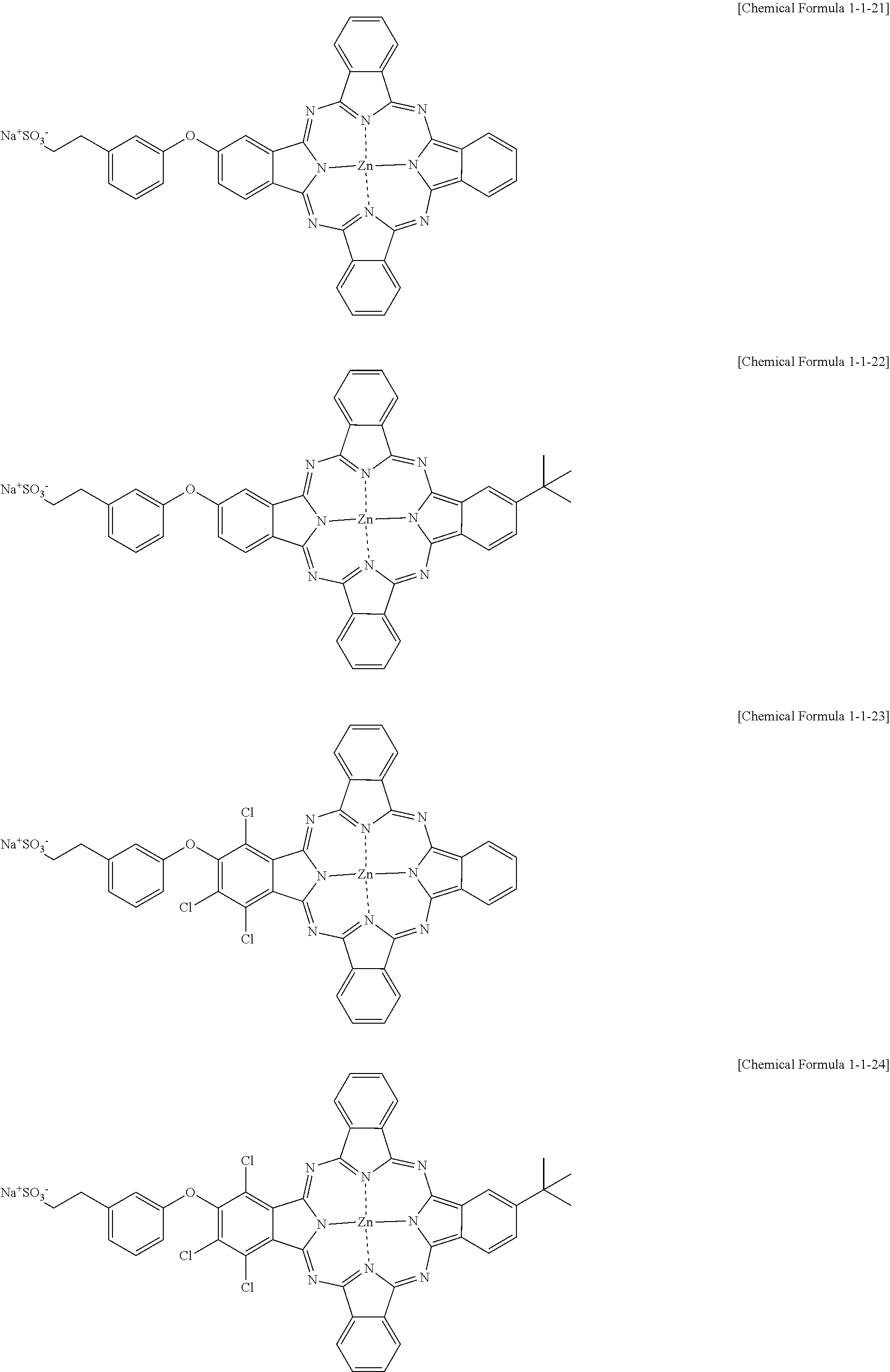

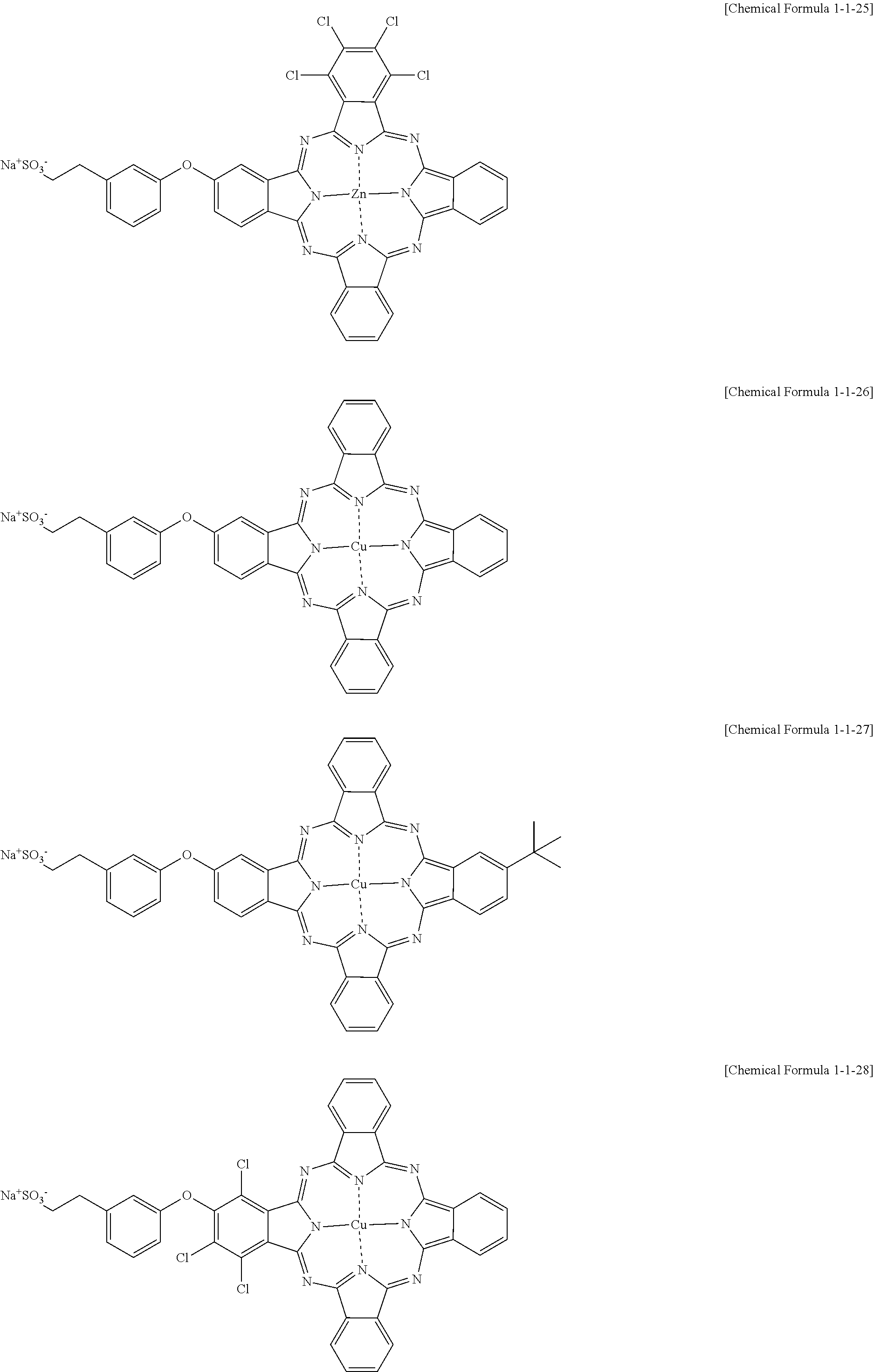

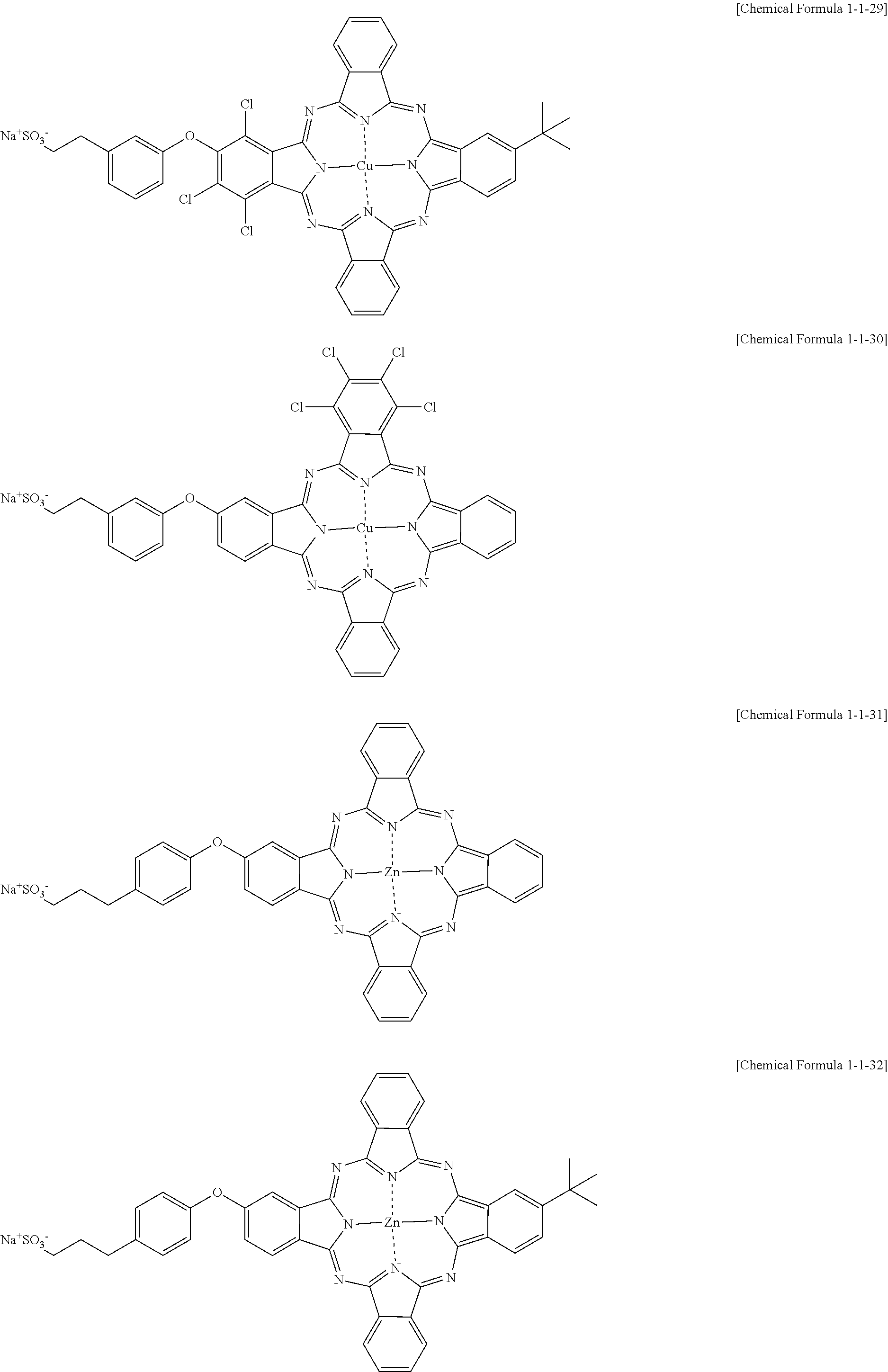

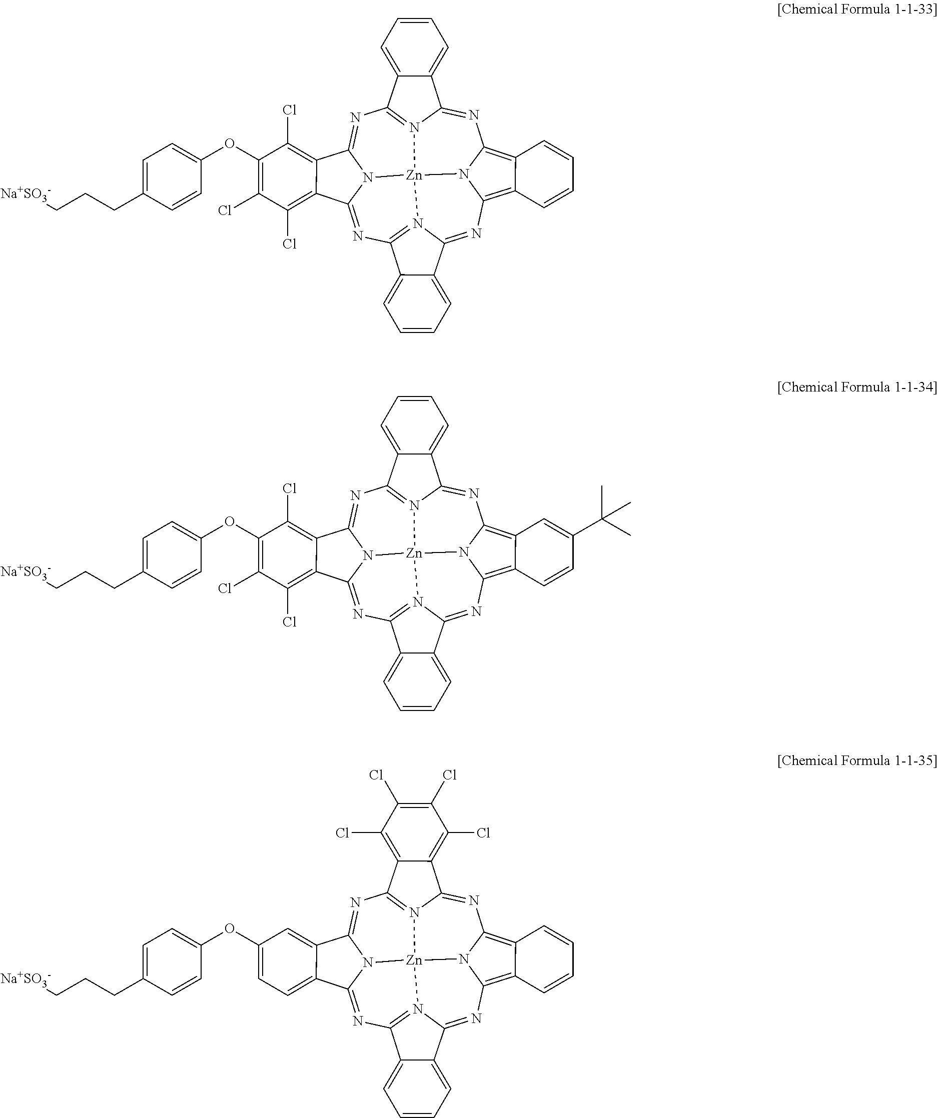

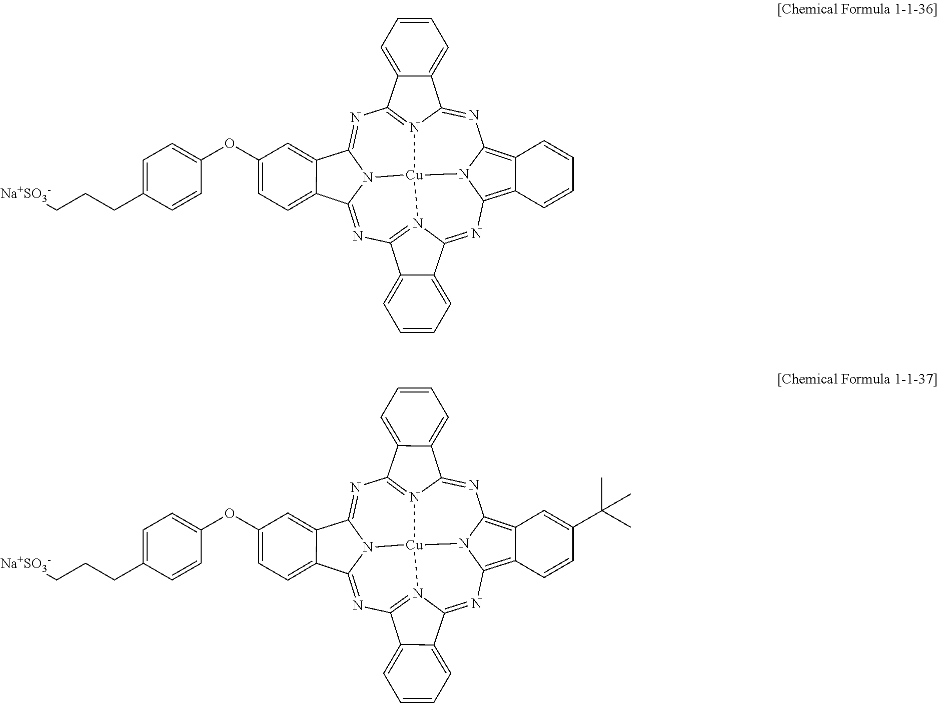

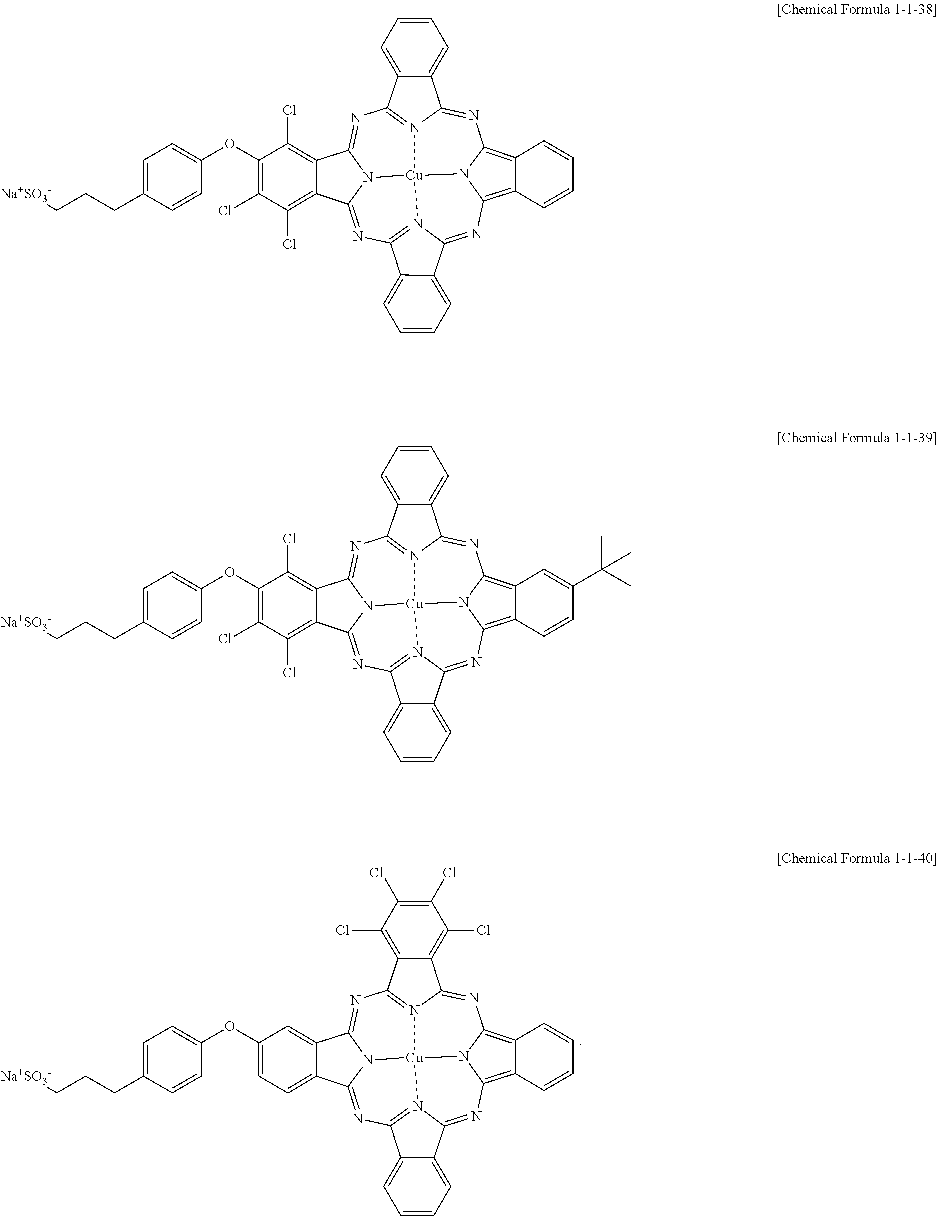

As described above, the dispersing aid represented by Chemical Formula 1 may have a phthalocyanine mother moiety that expresses blue color, and may help further improve the coloring power and contrast ratio of the photosensitive resin composition.

In an implementation, the dispersing aid represented by Chemical Formula 1 may have a maximum absorption wavelength (λₘₐₓ) of, e.g., about 450 nm to about 495 nm.

The dispersing aid represented by Chemical Formula 1 may be included in an amount of, e.g., about 0.5 wt % to about 6 wt %, about 1 wt % to about 5 wt %, or about 2 wt % to about 3 wt %, based on a total weight of the photosensitive resin composition.

In an implementation, a weight ratio of the dispersing aid represented by Chemical Formula 1 and the pigment may be, e.g., about 1:20 to about 1:70, about 1:30 to about 1:60, or about 1:40 to about 1:50.

In each of the above ranges, it is possible to improve the coloring power and contrast ratio while increasing the dispersibility and dispersion stability of the photosensitive resin composition according to the embodiment.

The colorant may include a pigment, and the pigment may include a green pigment, a blue pigment, a red pigment, a violet pigment, a yellow pigment, a black pigment, or the like.

The red pigment may include, e.g., C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, or the like in the color index, which may be used alone or in a mixture of two or more.

The violet pigment may include, e.g., C.I. Violet Pigment 23 (V.23), C.I. Violet Pigment 29, Dioxazine Violet, First Violet B, Methyl Violet Lake, Indanethrene Brilliant Violet, or the like in the color index, which may be used alone or in a mixture of two or more.

The green pigment may include, e.g., C.I. Green Pigment 7, C.I. Green Pigment 36, C.I. Green Pigment 58, C.I. Green Pigment 59, or the like in the color index, which may be used alone or in a mixture of two or more.

The blue pigment may include, e.g., copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16, or the like in the color index, which may be used alone or in a mixture of two or more.

The yellow pigment may include, e.g., an isoindoline pigment such as C.I. Yellow Pigment 185, C.I. Yellow Pigment 139, or the like, a quinophthalone pigment such as C.I. Yellow Pigment 138, a nickel complex pigment such as C.I. Yellow Pigment 150 in the color index, which may be used alone or in a mixture of two or more.

The black pigment may include, e.g., aniline black, perylene black, titanium black, carbon black, or the like in the color index, which may be used alone or in a mixture of two or more.

The above pigments may be used alone or in a mixture of two or more thereof. For example, a green pigment, a yellow pigment, or a mixture thereof may be used as the pigment.

The dispersant may help to uniformly disperse the pigment in the dispersion, and each of a nonionic, anionic, or cationic dispersant may be used. In an implementation, polyalkylene glycol or esters thereof, polyoxyalkylene, a polyhydric alcohol ester alkylene oxide adduct, an alcohol alkylene oxide adduct, a sulfonic acid ester, a sulfonic acid salt, a carboxylic acid ester, a carboxylic acid salt, an alkyl amide alkylene oxide adduct, alkyl amine, or the like may be used, and these may be used alone or in a mixture of two or more.

The pigment may be included in the photosensitive resin composition for color filters in the form of a dispersion. The pigment dispersion may further include a dispersion solvent, a dispersion resin, or the like, in addition to the pigment, the dispersant, and the dispersing aid. The solid pigment excluding the solvent may be included in an amount of, e.g., about 5 wt % to about 20 wt %, or about 8 wt % to about 15 wt %, based on a total weight of the pigment dispersion.

The solvent of the pigment dispersion may include, e.g., ethylene glycol acetate, ethyl cellosolve, propylene glycol methyl ether acetate, ethyl lactate, polyethylene glycol, cyclohexanone, propylene glycol methyl ether, or the like. In an implementation, the solvent may include, e.g., propylene glycol methyl ether acetate.

The dispersion resin may be an acrylic resin containing a carboxy group, which may help improve stability of the pigment dispersion and also help improve pixel patternability.

The colorant may further include a dye along with the pigment, and in this case, the resin composition of an embodiment may be a hybrid composition. In an implementation, the dye may include a metal complex dye.

The metal complex dye may be a compound having maximum absorbance in the wavelength range of about 200 nm to about 650 nm. When the compound has absorbance in the above range in order to match the color coordinates to the combination of dyes, the metal complex dye of all colors that dissolves in an organic solvent may be used.

In an implementation, the metal complex dye may be a green dye having maximum absorbance in a wavelength range of about 530 nm to about 680 nm, a yellow dye having maximum absorbance in a wavelength range of about 200 nm to about 400 nm, an orange dye having a maximum absorbance in a wavelength range of about 300 nm to about 500 nm, a red dye having maximum absorbance in a wavelength range of about 500 nm to about 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include, e.g., Mg, Ni, Cu, Co, Zn, Cr, Pt, Pd, or Fe.

The metal complex dye may be a complex of, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to about 5, e.g., about 5 to about 10, in a solvent used in the photosensitive resin composition according to an embodiment. The solubility may be obtained by an amount (g) of the dye dissolved in 100 g of the solvent. When the solubility of the metal complex dye is within the above ranges, compatibility with other components constituting the photosensitive resin composition according to an embodiment and coloring power may be secured, and precipitation of the dye may be prevented.

The solvent may include, e.g., propylene glycol monomethyl ether acetate (PGMEA), ethyl lactate (EL), ethylene glycol ethyl acetate (EGA), cyclohexanone (cyclohexanone), 3-methoxy-1-butanol, or a combination thereof.

In an implementation, it may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt %, based on a total weight of the photosensitive resin composition. When the metal complex dye is used in the above ranges, high luminance and contrast ratio can be exhibited in a desired color coordinate.

When the dye and the pigment are mixed and used, they may be mixed in a weight ratio of about 0.1:99.9 to about 99.9:0.1, e.g., about 1:9 to about 9:1. When mixed in the above weight ratio ranges, chemical resistance and maximum absorption wavelength may be controlled within an appropriate range, and high luminance and contrast ratio may be exhibited in a desired color coordinate.

The colorant may be included in an amount of about 5 wt % to about 50 wt %, e.g., about 6 wt % to about 40 wt %, or about 7 wt % to about 30 wt %, based on a total solid weight of the photosensitive resin composition. When the colorant is included within the above ranges, a coloring effect and developability are improved.

(B) Photopolymerizable Compound

The photopolymerizable compound may be a mono-functional or multi-functional ester of (meth)acrylic acid including at least one ethylenic unsaturated double bond.

The photopolymerizable compound may facilitate sufficient polymerization during exposure in a pattern-forming process and form a pattern having excellent heat resistance, light resistance, and chemical resistance due to the ethylenic unsaturated double bond.

Examples of the photopolymerizable compound may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Commercially available examples of the photopolymerizable compound may be as follows. The mono-functional (meth)acrylic acid ester may include Aronix M-101®, Aronix M-111®, Aronix M-114® (Toagosei Chemistry Industry Co., Ltd.); KAYARAD TC-110S®, KAYARAD TC-120S® (Nippon Kayaku Co., Ltd.); V-158®, V-2311® (Osaka Organic Chemical Ind., Ltd.), or the like. Examples of a difunctional (meth)acrylic acid ester may include Aronix M-210®, Aronix M-240®, Aronix M-6200® (Toagosei Chemistry Industry Co., Ltd.), KAYARAD HDDA®, KAYARAD HX-220®, KAYARAD R-604® (Nippon Kayaku Co., Ltd.), V-260®, V-312®, V-335 HP® (Osaka Organic Chemical Ind., Ltd.), and the like. Examples of a tri-functional (meth)acrylic acid ester may include Aronix M-309®, Aronix M-400®, Aronix M-405®, Aronix M-450®, Aronix M-710®, Aronix M-8030®, Aronix M-8060® (Toagosei Chemistry Industry Co., Ltd.); KAYARAD TMPTA®, KAYARAD DPCA-20®, KAYARAD DPCA-30®, KAYARAD DPCA-60®, KAYARAD DPCA-120® (Nippon Kayaku Co., Ltd.); V-295®, V-300®, V-360®, V-GPT®, V-3PA®, V-400® (Osaka Yuki Kayaku Kogyo Co. Ltd.), and the like. These may be used alone or as a mixture of two or more.

The photopolymerizable compound may be treated with acid anhydride to help improve developability.

The photopolymerizable compound may be included in an amount of about 0.1 wt % to about 20 wt %, e.g., about 1 wt % to about 15 wt %, or about 2 wt % to about 13 wt %, based on a total weight of the photosensitive resin composition. When the photopolymerizable compound is included within the above ranges, sufficient curing occurs during exposure in the pattern forming process, resulting in excellent reliability and excellent developability with an alkali developing solution.

(C) Photopolymerization Initiator

The photopolymerization initiator may be an initiator suitably used in a photosensitive resin composition, e.g., an acetophenone compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyldimethylketal, and the like.

Examples of the triazine compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include O-acyloxime-based compound, 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

The photopolymerization initiator may further include a carbazole compound, a diketone compound, a sulfonium borate compound, a diazo compound, an imidazole compound, a biimidazole compound, a fluorene compound, or the like, in addition to the other compounds.

The photopolymerization initiator may be used with a photosensitizer capable of causing a chemical reaction by absorbing light and becoming excited and then, transferring its energy.

Examples of the photosensitizer may include tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of about 0.1 wt % to about 5 wt %, e.g., about 1 wt % to about 3 wt %, based on a total weight of the photosensitive resin composition. When the photopolymerization initiator is included within the ranges, sufficient photopolymerization occurs during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

(D) Binder Resin

The binder resin may include an acrylic resin.

The acrylic resin may be a copolymer of a first ethylenic unsaturated monomer and a second ethylenic unsaturated monomer that is copolymerizable therewith, and may be a resin including at least one acryl repeating unit.

The first ethylenic unsaturated monomer may include an ethylenic unsaturated monomer including at least one carboxyl group and examples of the monomer may include acrylic acid, methacrylic acid, maleic acid, itaconic acid, fumaric acid, or a combination thereof.

The first ethylenic unsaturated monomer may be included in an amount of about 5 wt % to about 50 wt %, e.g., about 10 wt % to about 40 wt %, based on a total weight of the acrylic binder resin.

The second ethylenic unsaturated monomer may include an aromatic vinyl compound such as styrene, α-methylstyrene, vinyl toluene, vinylbenzylmethylether or the like; an unsaturated carboxylate ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated amino alkyl carboxylate ester compound such as 2-aminoethyl(meth)acrylate, 2-dimethylaminoethyl(meth)acrylate, or the like; a carboxylic acid vinyl ester compound such as vinyl acetate, vinyl benzoate, or the like; an unsaturated glycidyl carboxylate ester compound such as glycidyl(meth)acrylate, or the like; a vinyl cyanide compound such as (meth)acrylonitrile or the like; an unsaturated amide compound such as (meth)acrylamide, or the like; or the like, and may be used alone or as a mixture of two or more.

Examples of the acrylic resin may include a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

The binder resin may include an epoxy binder resin.

The binder resin may help improve heat resistance by further including an epoxy binder resin. The epoxy binder resin may include, e.g., a phenol novolac epoxy resin, a tetramethyl biphenyl epoxy resin, a bisphenol A epoxy resin, a bisphenol F epoxy resin, an alicyclic epoxy resin, or a combination thereof.

In an implementation, the binder resin including the epoxy binder resin may help secure dispersion stability of a colorant such as a pigment, which will be described below, and may help form a pixel having a desired resolution during a developing process.

The epoxy binder resin may be included in an amount of about 1 wt % to about 10 wt %, e.g., about 5 wt % to about 10 wt %, based on a total weight of the binder resin. When the epoxy binder resin is included in the above ranges, film residue ratio and chemical resistance may be greatly improved.

An epoxy equivalent weight of the epoxy resin may be, e.g., about 150 g/eq to about 200 g/eq. When an epoxy binder resin having an epoxy equivalent within the above range is included in the binder resin, there may be an advantageous effect in improving a curing degree of the formed pattern and fixing the colorant in the structure in which the pattern is formed.

The binder resin may be dissolved in a solvent in a solid form to form a photosensitive resin composition. In this case, the binder resin in the solid form may be about 0.1 wt % to about 30 wt %, e.g., about 20 wt % to about 30 wt %, based on a total weight of the binder resin solution dissolved in the solvent.

The binder resin may be included in an amount of, e.g., about 0.1 wt % to about 20 wt %, about 0.5 wt % to about 15 wt %, or about 1 wt % to about 10 wt %, based on a total solid weight of the photosensitive resin composition. When the binder resin is included within the above ranges, it is possible to obtain excellent surface smoothness due to excellent developability and improved crosslinking property during manufacture of the color filter.

(E) Solvent

The solvent may be a material that has compatibility with the colorant, the binder resin, the photopolymerizable compound, and the photopolymerization initiator but does not react.

Examples of the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. In an implementation, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, or the like may be also used.

Considering compatibility and reactivity, the solvent may include, e.g., propylene glycol monomethyl ether acetate (PGMEA), n-butyl acetate (n-BA), ethylene glycol dimethyl ether, or a combination thereof.

The solvent may be included in a balance amount, e.g., about 70 wt % to about 90 wt %, or about 80 wt % to about 90 wt %, based on a total weight of the photosensitive resin composition. When the solvent is included within the above ranges, it is possible to obtain a coating film having excellent coatability of the photosensitive resin composition and excellent flatness.

(F) Other Additives

In an implementation, the photosensitive resin composition may further include an additive, e.g., malonic acid; 3-amino-1,2-propanediol; a coupling agent including a vinyl group or a (meth)acryloxy group; a leveling agent; a surfactant; or a radical polymerization initiator, in order to help prevent stains or spots during the coating, to help adjust leveling, or to help prevent pattern residue due to non-development.

The additives may be adjusted according to desired physical properties.

The coupling agent may include a silane coupling agent, and examples of the silane coupling agent may include, e.g., trimethoxysilyl benzoic acid, γ methacryl oxypropyl trimethoxysilane, vinyl triacetoxysilane, vinyl trimethoxysilane, γ isocyanate propyl triethoxysilane, γ glycidoxy propyl trimethoxysilane, or R epoxycyclohexyl)ethyltrimethoxysilane, which may be used alone or in mixture of 2 or more types.

The silane coupling agent may be included in an amount of, e.g., about 0.01 part by weight to about 1 part by weight, based on 100 parts by weight of the photosensitive resin composition.

In an implementation, the photosensitive resin composition for color filters may further include a surfactant, e.g., a fluorine surfactant.

Examples of the fluorine surfactant may include F-482, F-484, and F-478 of DIC Co., Ltd.

The surfactant may be included in an amount of, e.g., about 0.01 wt % to about 5 wt % or about 0.01 wt % to about 2 wt % based on a total weight of the photosensitive resin composition. When the surfactant is included in the above ranges, generation of foreign substances after development may be avoided.

In an implementation, other additives, e.g., an antioxidant, a stabilizer, or the like may be added to the photosensitive resin composition within an amount that does not impair physical properties.

(Photosensitive Resin Layer, Color Filter, and Display Device)

According to another embodiment, a photosensitive resin layer manufactured using the photosensitive resin composition according to the embodiment may be provided.

The photosensitive resin layer of an embodiment may be divided into a color positive photoresist composition and a color negative photoresist composition.

The photosensitive resin layer of an embodiment may be a color negative photoresist. This may have an advantage that coloring by the photoresist may not occur and the photosensitivity may be relatively higher than that of the positive photoresist.

In an implementation, a color filter manufactured using the photosensitive resin composition described above is provided.

A method of manufacturing the color filter of an embodiment is as follows.

The aforementioned photosensitive resin composition may be coated to form an about 0.5 μm to about 10 μm-thick photosensitive resin composition layer on a glass substrate using a method such as spin coating, roller coating, spray coating, or the like.

Subsequently, the substrate having the photosensitive resin composition layer may be irradiated by light or other radiation to form a pattern required for a color filter. The irradiation may be performed by using UV, an electron beam, or an X-ray as a light or radiation source, and the UV may be irradiated, e.g., in a region of about 190 nm to about 450 nm or about 200 nm to about 400 nm. The irradiation may be performed by further using a photoresist mask. After performing the irradiation process in this way, the photosensitive resin composition layer exposed to the light source may be treated with a developing solution. A non-exposed region of the photosensitive resin composition layer may be dissolved and forms the pattern for a color filter. This process may be repeated as many times as the number of colors, obtaining a color filter having a desired pattern. In an implementation, when the image pattern obtained through development in the above process is cured by reheating or radiating an actinic ray thereinto, crack resistance, solvent resistance, and the like may be improved.

According to another embodiment, a display device including the color filter described above is provided.

The display device may be a liquid crystal display device, a CMOS image sensor, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis Example 1

### (1) Preparation of Intermediate 1-1

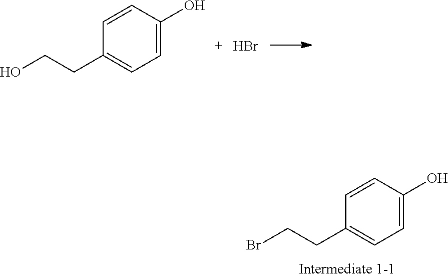 [SMILES: OCCc1ccc(O)cc1 ; Br ; Oc1ccc(CCBr)cc1]

2-(4-hydroxyphenyl)ethanol (10 g) and bromic acid (100 g) were added to a 250 ml flask and after connecting a condenser thereto, a nitrogen atmosphere was provided, and stirred while heating 80° C. When a reaction was completed, the resultant was extracted with MC (methylene chloride). An organic layer extracted therefrom was treated with MgSO₄ to remove moisture and then, concentrated and vacuum-dried, obtaining Intermediate 1-1.

### (2) Preparation of Intermediate 1-2

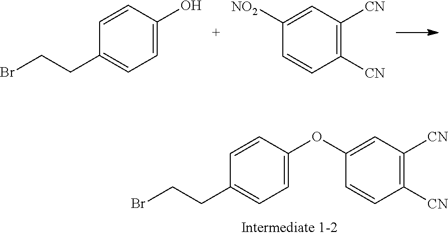 [SMILES: Oc1ccc(CCBr)cc1 ; N#Cc1ccc([N+](=O)[O-])cc1C#N ; N#Cc1ccc(Oc2ccc(CCBr)cc2)cc1C#N]

Intermediate 1-1 (5 g) according to Synthesis Example 1, 4-nitrophthalonitrile (4.31 g), K₂CO₃ (6.19 g), and N,N-dimethylformamide (DMF) (25 ml) were added to a 100 ml flask and then, stirred while heating at 70° C. When the reaction was completed, the resultant was extracted with EA (ethyl acetate). After the extraction, concentration and purification through column chromatography were performed. After the purification, Intermediate 1-2 was obtained by vacuum-drying.

### (3) Preparation of Intermediate 1-3

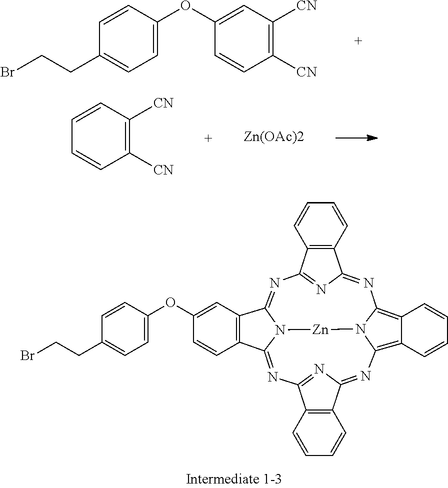

Intermediate 1-9 (3 g), phthalonitrile (3.52 g), 1,8-diazabicycloundec-7-ene (1.98 g), and 1-pentenol (30 g) were added to a 100 ml flask and then, heated at 90° C. until the solids were dissolved, and then, zinc acetate (1.68 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and crystallized by adding methanol. The crystallized solid was filtered and vacuum-dried, obtaining a compound represented by Intermediate 1-3.

### (4) Preparation of Compound Represented by Chemical Formula 1-1-1

Intermediate 1-3 (1.0 g), sodium sulfite (0.32 g), and DMF (10 ml) were put in a 100 mL flask, a condenser was connected thereto and a nitrogen atmosphere was provided. The mixture was stirred while heating at 120° C., and when a reaction was completed, the resultant was extracted with MC. The extracted organic layer was treated with MgSO₄ to remove moisture and then, concentrated. A solid obtained therefrom was dissolved by appropriately adding MC and then, crystallized by adding methanol. The crystallized solid was filtered and vacuum-dried, obtaining a compound represented by Chemical Formula 1-1-1.

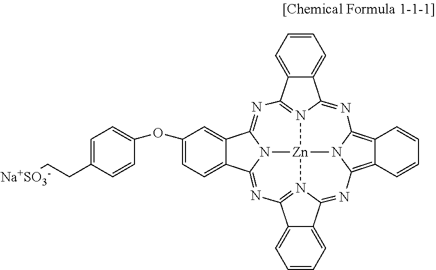

MALDI-TOF MS. 777 m/z

### Synthesis Example 2

### (1) Synthesis of Intermediate 1-4

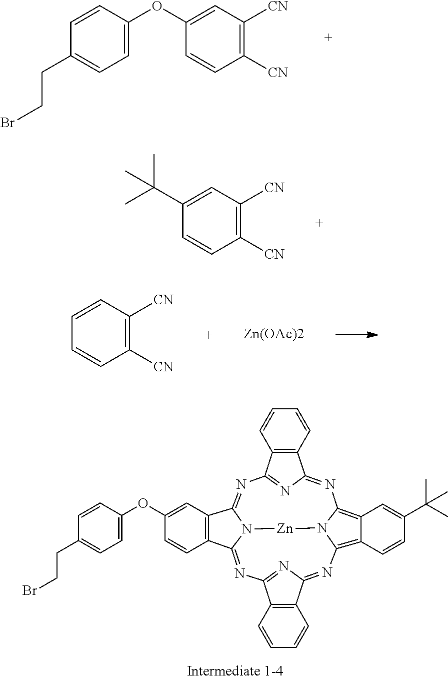

Intermediate 1-2 (4 g), phthalonitrile (2.75 g), 4-tert-butylphthalonitrile (1.98 g), 1,8-diazabicycloundec-7-ene (2.08 g), and 1-pentenol (30 g) were added to a 100 ml flask and heated at 90° C. until the solids were dissolved, and then, zinc acetate (1.97 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and then, crystallized by adding methanol. The crystallized solid was filtered and vacuum-dried to obtain Intermediate 1-4.

### (2) Preparation of Compound Represented by Chemical Formula 1-1-2

Intermediate 1-4 (1.0 g), sodium sulfite (0.33 g), and DMF (10 ml) were put in a 100 mL flask, and a condenser was connected thereto and a nitrogen atmosphere was provided. The mixture was stirred while heating at 120° C. When a reaction was completed, the resultant was extracted with MC. An organic layer extracted therefrom was treated with M-SO₄ to remove moisture and then, concentrated. A solid obtained therefrom was dissolved by appropriately adding MC and then, crystallized by adding methanol. The crystallized solid was filtered and vacuum-dried, obtaining a compound represented by Chemical Formula 1-1-2.

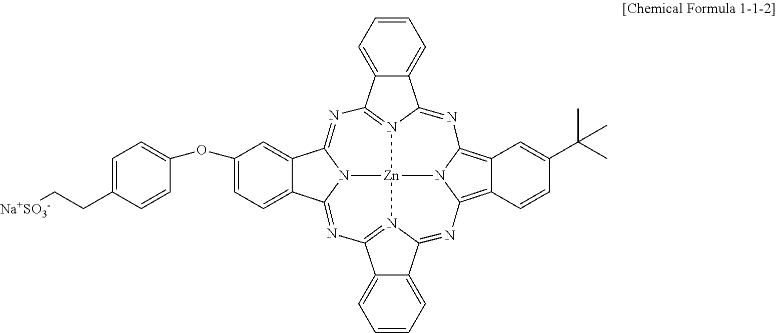

MALDI-TOF MS: 834 m/z

### Synthesis Example 3

### (1) Preparation of Intermediate 1-5

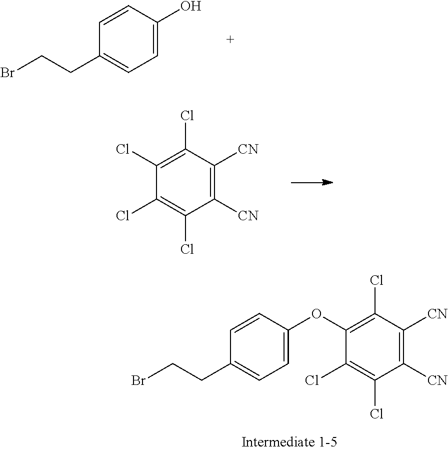 [SMILES: Oc1ccc(CCBr)cc1 ; N#Cc1c(Cl)c(Cl)c(Cl)c(Cl)c1C#N ; N#Cc1c(Cl)c(Cl)c(Oc2ccc(CCBr)cc2)c(Cl)c1C#N]

Intermediate 1-1 (5 g), 3,4,5,6-tetrachlorophthalonitrile (6.61 g), K₂CO₃ (6.19 g), and N,N-dimethylformamide (DMF) (25 ml) were added to a 100 ml flask and then, stirred while heating at 70° C. When the reaction was completed, the resultant was extracted with EA (ethyl acetate). After the extraction, concentration and purification through column chromatography were conducted. After the purification, Intermediate 1-5 was obtained through vacuum-drying.

### (2) Preparation of Intermediate 1-6

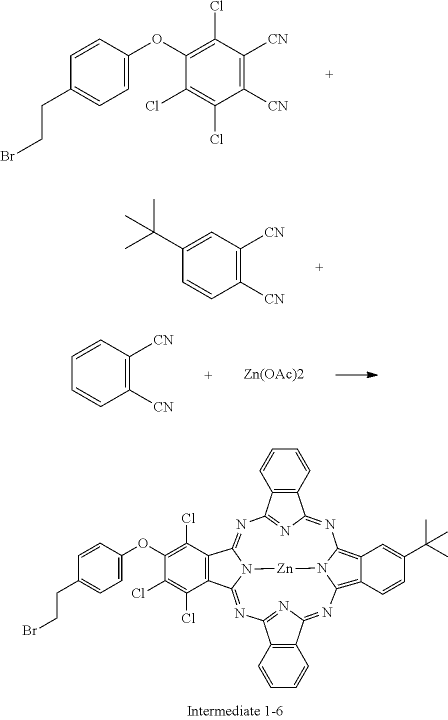

Intermediate 1-5 (2 g), phthalonitrile (1.19 g), 4-tert-butylphthalonitrile (0.86 g), 1,8-diazabicycloundec-7-ene (2.08 g), and 1-pentenol (15 g) were added to a 100 ml flask and then, heated at 90° C. until the solids were dissolved, and zinc acetate (0.85 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and crystallized by adding methanol. The crystallized solid was filtered and vacuum-dried, obtaining Intermediate 1-6.

### (3) Preparation of Compound Represented by Chemical Formula 1-1-4

Intermediate 1-6 (1.0 g), Na₂SO₃ (0.54 g), and DMF (10 ml) were put in a 100 mL flask, a condenser was connected thereto, and a nitrogen atmosphere was provided. The mixture was stirred while heating at 60° C., and when a reaction was completed, the resultant was extracted with MC. An organic layer extracted therefrom was treated with MgSO₄ to remove moisture and then, concentrated. A solid obtained therefrom was dissolved by appropriately adding MC and then, crystallized with methanol. The crystallized solid was filtered and vacuum-dried, obtaining a compound represented by Chemical Formula 1-1-4.

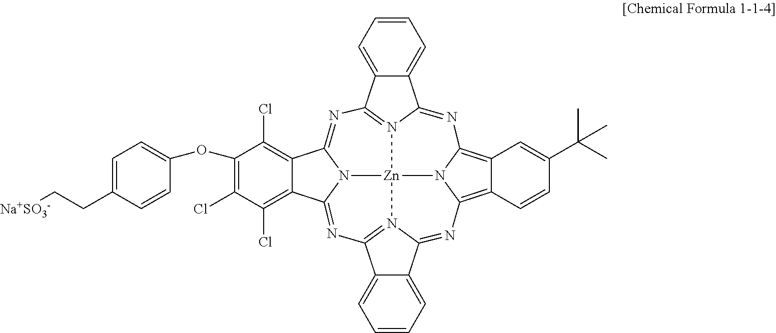

MALDI-TOF MS. 937 m/z

### Synthesis Example 4

### (1) Synthesis of Intermediate 1-7

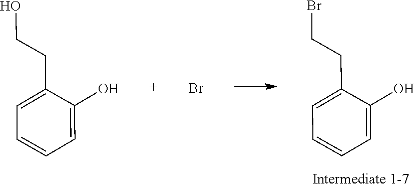 [SMILES: OCCc1ccccc1O ; Br ; Oc1ccccc1CCBr]

2-hydroxyphenethyl alcohol (10 g) and bromine acid (100 g) were added to a 250 ml flask and after connecting a condenser thereto, a nitrogen atmosphere was provided, and then, stirred while heating at 80° C. When a reaction was completed, the resultant was extracted with MC (dichloromethane). An organic layer extracted therefrom was treated with MgSO₄ to remove moisture and then, concentrated and vacuum-dried, obtaining Intermediate 1-7.

### (2) Preparation of Intermediate 1-8

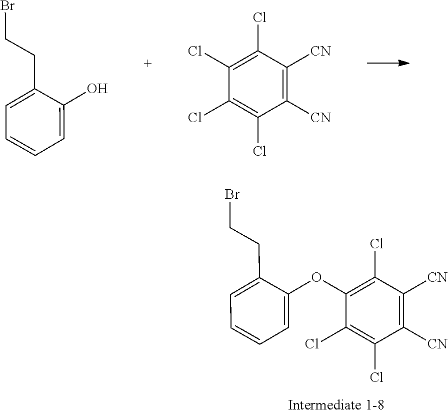 [SMILES: Oc1ccccc1CCBr ; N#Cc1c(Cl)c(Cl)c(Cl)c(Cl)c1C#N ; N#Cc1c(Cl)c(Cl)c(Oc2ccccc2CCBr)c(Cl)c1C#N]

Intermediate 1-7 (5 g), 3,4,5,6-tetrachlorophthalonitrile (6.61 g), K₂CO₃ (6.19 g), and N,N-dimethylformamide (DMF) (25 ml) were added to a 100 ml flask and then, stirred while heating at 70° C. When the reaction was completed, the resultant was extracted with EA (ethyl acetate). After the extraction, concentration and purification through column chromatography were conducted. After the purification, Intermediate 1-8 was obtained through vacuum-drying.

### (3) Preparation of Intermediate 1-9

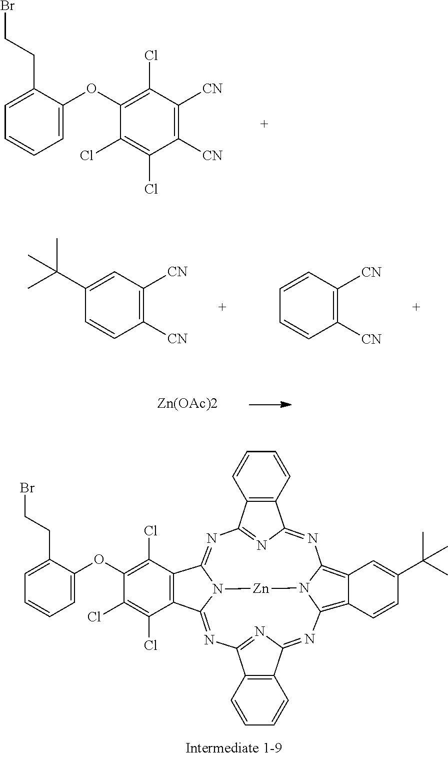

Intermediate 1-8 (2 g), phthalonitrile (1.19 g), 4-tert-butylphthalonitrile (0.86 g), 1,8-diazabicycloundec-7-ene (2.08 g), and 1-pentenol (15 g) were added to a 100 ml flask and then, dissolved until the solids were dissolved by heating at 90° C., and zinc acetate (0.85 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and then, crystallized by adding methanol. The crystallized solid was filtered and vacuum-dried, obtaining Intermediate 1-9.

### (4) Preparation of Compound Represented by Chemical Formula 1-1-14

Intermediate 1-9 (1.0 g), Na₂SO₃ (0.54 g), and DMF (10 ml) were put in a 100 mL flask, a condenser was connected thereto, and a nitrogen atmosphere was provided. The mixture was stirred while heating at 60° C., and when a reaction was completed, the resultant was extracted with MC. An organic layer extracted therefrom was treated with MgSO₄ to remove moisture and then, concentrated. A solid obtained therefrom was dissolved by appropriately adding MC and then, crystallized by adding methanol. The crystallized solid was filtered and vacuum-dried, obtaining a compound represented by Chemical Formula 1-1-14.

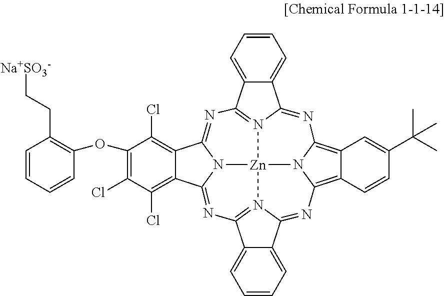

MALDI-TOF MS: 937 m/z

### Synthesis Example 5

### (1) Preparation of Intermediate 1-10

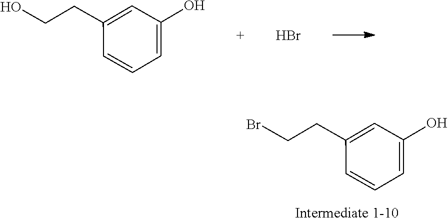 [SMILES: OCCc1cccc(O)c1 ; Br ; Oc1cccc(CCBr)c1]

2-(3-hydroxyphenyl)ethanol (10 g) and bromic acid (100 g) were added to a 250 ml flask, a condenser was connected thereto, a nitrogen atmosphere was provided, and then, stirred while heating at 80° C., and when a reaction was completed, the resultant was extracted with MC (dichloromethane). An organic layer extracted therefrom was treated with MgSO₄ to remove moisture and then, concentrated vacuum-dried, obtaining Intermediate 1-10.

### (2) Preparation of Intermediate 1-11

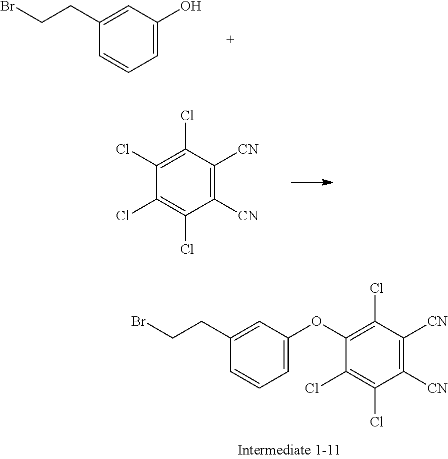 [SMILES: Oc1cccc(CCBr)c1 ; N#Cc1c(Cl)c(Cl)c(Cl)c(Cl)c1C#N ; N#Cc1c(Cl)c(Cl)c(Oc2cccc(CCBr)c2)c(Cl)c1C#N]

Intermediate 1-10 (5 g), 3,4,5,6-tetrachlorophthalonitrile (6.61 g), K₂CO₃ (6.19 g), and N,N-dimethylformamide (DMF) (25 ml) were added to a 100 ml flask and then, stirred while heating at 70° C. When the reaction was completed, the resultant was extracted with EA (ethyl acetate). After the extraction, concentration and purification through column chromatography were conducted. After the purification, Intermediate 1-11 was obtained through vacuum-drying.

### (3) Preparation of Intermediate 1-12

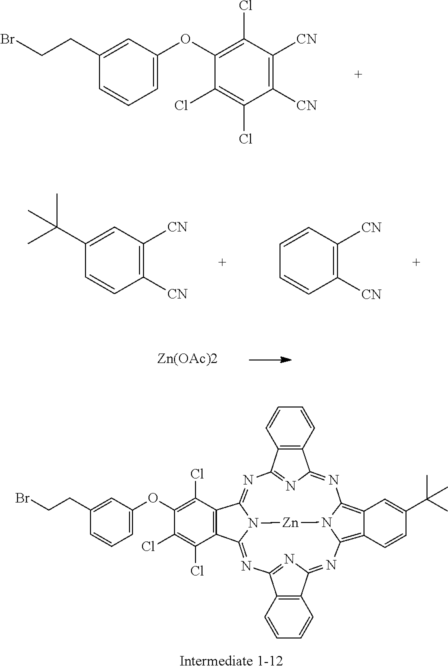

Intermediate 1-11 (2 g), phthalonitrile (1.19 g), 4-tert-butylphthalonitrile (0.86 g), 1,8-diazabicycloundec-7-ene (2.08 g), and 1-pentenol (15 g) were added to a 100 ml flask and heated at 90° C. until the solids were dissolved, and zinc acetate (0.85 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and then, crystallized by adding methanol. The crystallized solid was filtered and vacuum-dried, obtaining Intermediate 1-9.

### (4) Preparation of Compound Represented by Chemical Formula 1-1-14

Intermediate 1-12 (1.0 g), Na₂SO₃ (0.54 g), and DMF (10 ml) were put in a 100 mL flask, a condenser was connected thereto, and a nitrogen atmosphere was provided. The mixture was stirred while heating at 60° C., and when a reaction was completed, the resultant was extracted with MC. An organic layer extracted therefrom was treated with MgSO₄ to remove moisture and then, concentrated. A solid obtained therefrom was dissolved by appropriately adding MC and then, crystallized by adding methanol. The crystallized solid was filtered and vacuum-dried, obtaining a compound represented by Chemical Formula 1-1-24.

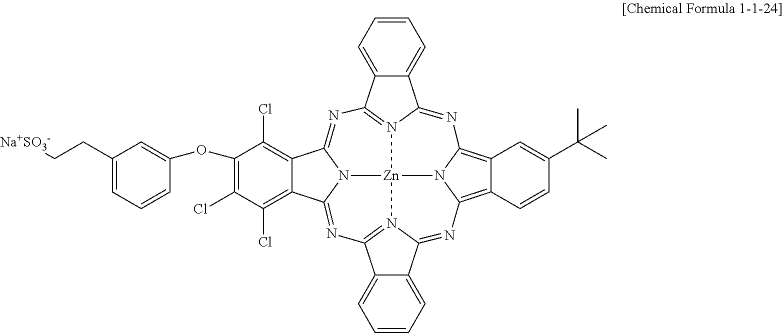

MALDI-TOF MS. 937 m/z

### Synthesis Example 6

### (1) Preparation of Intermediate 1-13

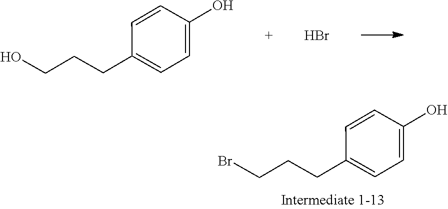 [SMILES: OCCCc1ccc(O)cc1 ; Br ; Oc1ccc(CCCBr)cc1]

3-(4-hydroxyphenyl)-1-propanol (10 g) and bromic acid (100 g) were added to a 250 ml flask and after connecting a condenser thereto, a nitrogen atmosphere was prepared, and the mixture was stirred while heating at 80° C. When a reaction was completed, the resultant was extracted by MC (dichloromethane). An organic layer extracted therefrom was treated with MgSO₄ to remove moisture and then, concentrated and vacuum-dried, obtaining Intermediate 1-13.

### (2) Preparation of Intermediate 1-13

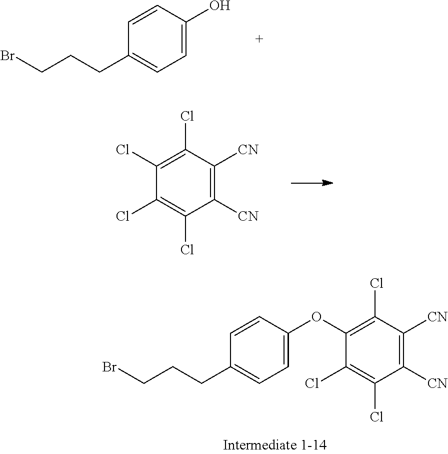 [SMILES: Oc1ccc(CCCBr)cc1 ; N#Cc1c(Cl)c(Cl)c(Cl)c(Cl)c1C#N ; N#Cc1c(Cl)c(Cl)c(Oc2ccc(CCCBr)cc2)c(Cl)c1C#N]

Intermediate 1-13 (5 g), 3,4,5,6-tetrachlorophthalonitrile (6.18 g), K₂CO₃ (6.08 g), and N,N-dimethylformamide (DMF) (25 ml) were added to a 100 ml flask and then, stirred while heating at 70° C. When the reaction was completed, the resultant was extracted with EA (ethyl acetate). After the extraction, concentration and purification through column chromatography were performed. After the purification, Intermediate 1-14 was obtained through vacuum-drying.

### (3) Preparation of Intermediate 1-15

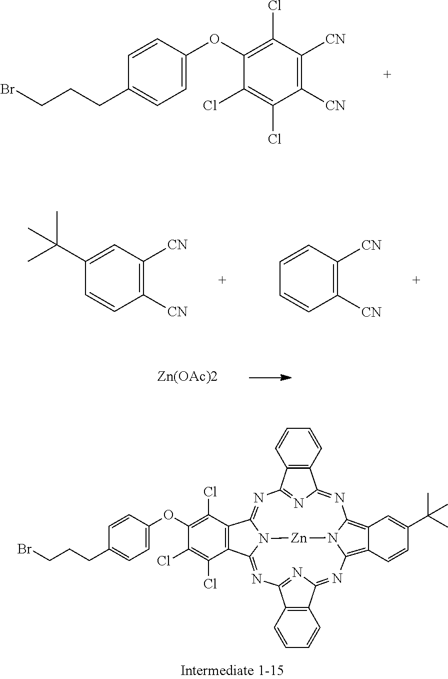

Intermediate 1-14 (2 g), phthalonitrile (1.15 g), 4-tert-butylphthalonitrile (0.83 g), 1,8-diazabicycloundec-7-ene (2.08 g), and 1-pentenol (15 g) were added to a 100 ml flask and heated at 90° C. until the solids were dissolved, and zine acetate (0.83 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and then, crystallized by adding methanol. The crystallized solid was filtered and vacuum-dried, obtaining Intermediate 1-15.

### (5) Preparation of Compound Represented by Chemical Formula 1-1-34

Intermediate 1-15 (1.0 g), Na₂SO₃ (0.27 g), and DMF (10 ml) were put in a 100 mL flask, a condenser was connected thereto, and a nitrogen atmosphere was provided. The mixture was stirred while heating at 60° C., and when a reaction was completed, the resultant was extracted with MC. An organic layer extracted therefrom was treated with MgSO₄ to remove moisture and then, concentrated. A solid obtained therefrom was dissolved by appropriately adding MC and then, crystallized by adding methanol. The crystallized solid was filtered and vacuum-dried, obtaining a compound represented by Chemical Formula 1-1-34.

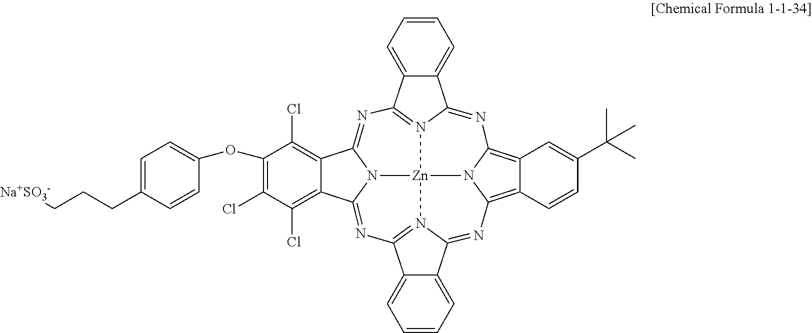

MALDI-TOF MS. 951 m/z

### Comparative Synthesis Example 1

### (1) Preparation of Intermediate 1-9

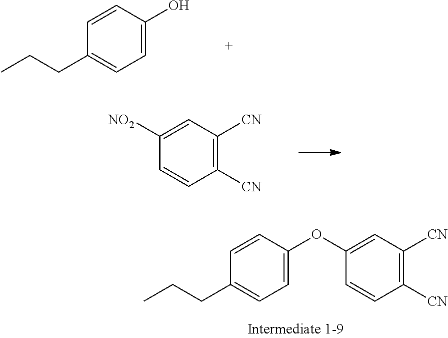

4-propylphenol (5 g), 4-nitrophthalonitrile (6.35 g), K₂CO₃ (6.08 g), and N,N-dimethylformamide (DMF) (25 ml) were added to a 100 ml flask and then, stirred while heating at 70° C. When the reaction was completed, the resultant was extracted with EA (ethyl acetate). After the extraction, concentration and purification through column chromatography were conducted. After the purification, Intermediate 1-15 was obtained through vacuum-drying.

### (2) Preparation of Compound Represented by Chemical Formula A

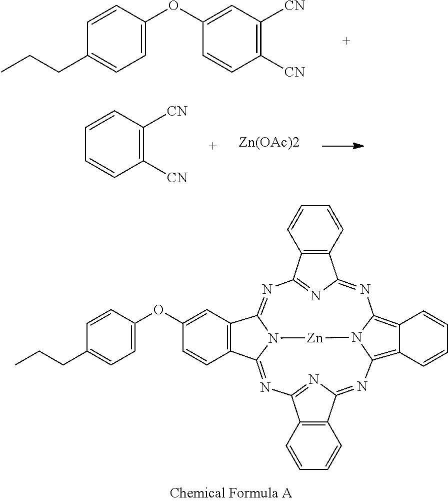

Intermediate 1-9 (3 g), phthalonitrile (4.40 g), 1,8-diazabicycloundec-7-ene (2.08 g), and 1-pentenol (30 g) were added to a 100 ml flask and then, heated at 90° C. until the solids were dissolved, and zinc acetate (2.10 g) was added thereto and then, stirred while heating at 140° C. When the reaction was completed, methanol was used for a precipitation, and a precipitate therefrom was filtered and vacuum-dried. The dried solid was purified through column chromatography. The purified solid was dissolved by appropriately adding MC and then, crystallized by adding methanol. The crystallized solid was filtered and vacuum-dried, obtaining a compound represented by Chemical Formula A.

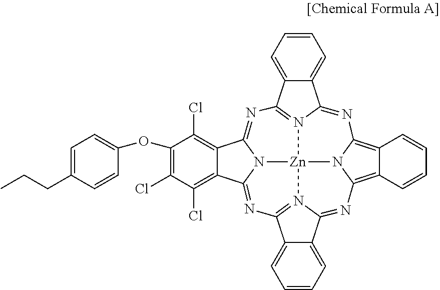

MALDI-TOF MS: 712.11 m/z

### Preparation of Green Pigment Dispersion

Each green pigment dispersion according to Preparation Examples 1 to 11 and Preparation Comparative Examples 1 and 2 was prepared to have a composition shown in Tables 1 to 3.

Specifically, a green pigment, a dispersant, a dispersing aid, and a solvent were mixed and then, dispersed by adding 300 parts by weight of zirconia beads (diameter: 0.4 μm) based on 100 parts by weight of this mixture thereto and using a paint shaker for 3 hours, and then, the zirconia beads were removed by filtering, obtaining each green pigment dispersion.

TABLE 1
(unit: wt %)

| | | Preparation | Preparation | Preparation | Preparation | Preparation | Preparation |
|---|---|---|---|---|---|---|---|
| | | Example 1 | Example 2 | Example 3 | Example 4 | Example 5 | Example 6 |
| Green pigment | | 12.0 | 12.0 | 12.0 | 12.0 | 12.0 | 12.0 |
| Dispersant | | 2.5 | 2.5 | 2.5 | 2.5 | 2.5 | 2.5 |
| Dispersing aid | Synthesis Example 1 | 0.5 | — | — | — | — | — |
| | Synthesis Example 2 | — | 0.5 | — | — | — | — |
| | Synthesis Example 3 | — | — | 0.5 | — | — | — |
| | Synthesis Example 4 | — | — | — | 0.5 | — | — |
| | Synthesis Example 5 | — | — | — | — | 0.5 | — |
| | Synthesis Example 6 | — | — | — | — | — | 0.5 |

| | | | | | | |
|---|---|---|---|---|---|---|
| Solvent | 85.0 | 85.0 | 85.0 | 85.0 | 85.0 | 85.0 |

TABLE 2
(unit: wt %)

| | | Preparation | Preparation | Preparation | Preparation | Preparation | Preparation |
|---|---|---|---|---|---|---|---|
| | | Example 7 | Example 8 | Example 3 | Example 9 | Example 10 | Example 11 |
| Green pigment | | 12.0 | 12.0 | 12.0 | 12.0 | 12.0 | 12.0 |
| Dispersant | | 2.5 | 2.5 | 2.5 | 2.5 | 2.5 | 2.5 |
| Dispersing | Synthesis Example 1 | — | — | — | — | — | — |
| aid | Synthesis Example 2 | — | — | — | — | — | — |
| | Synthesis Example 3 | 0.3 | 0.4 | 0.5 | 0.6 | 1.0 | 1.2 |
| | Synthesis Example 4 | — | — | — | — | — | — |
| | Synthesis Example 5 | — | — | — | — | — | — |
| | Synthesis Example 6 | — | — | — | — | — | — |

| | | | | | | |
|---|---|---|---|---|---|---|
| Solvent | 85.2 | 85.1 | 85.0 | 84.9 | 84.5 | 84.3 |

TABLE 3
(unit: wt %)

| | | Comparative | Comparative |
|---|---|---|---|
| | | Preparation | Preparation |
| | | Example 1 | Example 2 |
| Green pigment | | 12.0 | 12.0 |
| Dispersant | | 2.5 | 2.5 |
| Dispersing aid | Comparative Synthesis | — | 0.5 |
| | Example 1 | | |

| | | |
|---|---|---|
| Solvent (PGMEA) | 85.5 | 85.0 |

The materials used in Tables 1 to 3 are as follows.

Green Pigment: C.I. PIGMENT Green 58 (G58)

Dispersant: BYK-LPN6919 (Manufacturer: BYK)

Dispersion aid: Each compound of Synthesis Examples 1 to 6 and Comparative Synthesis Example 1

Solvent: Propylene Glycol Monomethylether Acetate (PGMEA)

Preparation of Yellow Pigment Dispersion

Yellow pigment dispersion was prepared by mixing 12.0 parts by weight of a yellow pigment (C.I. PIGMENT Yellow 138), 3.0 parts by weight of a dispersant (BYK-LPN6919, manufacturer: BYK-Chemie GmbH), and 85.0 parts by weight of a solvent (propylene glycol monomethylether acetate, PGMEA), adding 300 parts by weight of zirconia beads (diameter: 0.4 m) thereto based on 100 parts by weight of the mixture, shaking them to disperse the mixture with a paint shaker for 3 hours, and removing the zirconia beads by filtering.

### Preparation of Photosensitive Resin Compositions

Each photosensitive resin composition according to Examples 1 to 11 and Comparative Examples 1 and 2 was prepared to have a composition shown in Tables 4 to 6.

Specifically, the green pigment dispersion, the yellow pigment dispersion, a photopolymerizable monomer, a photopolymerization initiator, a binder resin, and a solvent were mixed, preparing each photosensitive coloring resin composition.

TABLE 4

| | | | Example | Example | Example | Example | Example | Example |
|---|---|---|---|---|---|---|---|---|
| | | | 1 | 2 | 3 | 4 | 5 | 6 |
| (A) | Green | Preparation | 20.0 | — | — | — | — | — |
| Colorant | pigment | Example 1 | | | | | | |
| | dispersion | Preparation | — | 20.0 | — | — | — | — |
| | | Example 2 | | | | | | |
| | | Preparation | — | — | 20.0 | — | — | — |
| | | Example 3 | | | | | | |
| | | Preparation | — | — | — | 20.0 | — | — |
| | | Example 4 | | | | | | |
| | | Preparation | — | — | — | — | 20.0 | — |
| | | Example 5 | | | | | | |
| | | Preparation | — | — | — | — | — | 20.0 |
| | | Example 6 | | | | | | |

| | | | | | | |
|---|---|---|---|---|---|---|
| Yellow pigment dispersion | 15.0 | 15.0 | 15.0 | 15.0 | 15.0 | 15.0 |

| (B) Photopolymerization | DPHA | 5.0 | 5.0 | 5.0 | 5.0 | 5.0 | 5.0 |
|---|---|---|---|---|---|---|---|
| monomer | | | | | | | |
| (C) Photopolymerization | A1 | 1.0 | 1.0 | 1.0 | 1.0 | 1.0 | 1.0 |
| initiator | A2 | 0.5 | 0.5 | 0.5 | 0.5 | 0.5 | 0.5 |
| (D) Binder resin | | 3.5 | 3.5 | 3.5 | 3.5 | 3.5 | 3.5 |
| (E) Solvent | PGMEA | 56.0 | 56.0 | 56.0 | 56.0 | 56.0 | 56.0 |

TABLE 5

| | | | Example | Example | Example | Example | Example | Example |
|---|---|---|---|---|---|---|---|---|
| | | | 7 | 8 | 3 | 9 | 10 | 11 |
| (A) | Green | Preparation Example 7 | 20.0 | — | — | — | — | — |
| Colorant | pigment | Preparation Example 8 | — | 20.0 | — | — | — | — |
| | dispersion | Preparation Example 3 | — | — | 20.0 | — | — | — |
| | | Preparation Example 9 | — | — | — | 20.0 | — | — |
| | | Preparation Example 10 | — | — | — | — | 20.0 | — |
| | | Preparation Example 11 | — | — | — | — | — | 20.0 |

| | | | | | | |
|---|---|---|---|---|---|---|
| Yellow pigment dispersion | 15.0 | 15.0 | 15.0 | 15.0 | 15.0 | 15.0 |

| (B) | DPHA | 5.0 | 5.0 | 5.0 | 5.0 | 5.0 | 5.0 |
|---|---|---|---|---|---|---|---|
| Photopolymerization | | | | | | | |
| monomer | | | | | | | |
| (C) | A1 | 1.0 | 1.0 | 1.0 | 1.0 | 1.0 | 1.0 |
| Photopolymerization | A2 | 0.5 | 0.5 | 0.5 | 0.5 | 0.5 | 0.5 |
| initiator | | | | | | | |
| (D) Binder resin | | 3.5 | 3.5 | 3.5 | 3.5 | 3.5 | 3.5 |
| (E) Solvent | PGMEA | 56.0 | 56.0 | 56.0 | 56.0 | 56.0 | 56.0 |

TABLE 6

| | | | Comparative | Comparative |
|---|---|---|---|---|
| | | | Example 1 | Example 2 |
| (A) | Green pigment | Preparation | 20.0 | — |
| Colorant | dispersion | Comparative | | |
| | | Example 1 | | |
| | | Preparation | — | 20.0 |
| | | Comparative | | |
| | | Example 2 | | |

| | | |
|---|---|---|
| Yellow pigment dispersion | 15.0 | 15.0 |

| (B) Photopolymerization | DPHA | 5.0 | 5.0 |
|---|---|---|---|
| monomer | | | |
| (C) Photopolymerization | C-1 | 1.0 | 1.0 |
| initiator | C-2 | 0.5 | 0.5 |
| (D) Binder resin | | 3.5 | 3.5 |
| (E) Solvent | PGMEA | 56.0 | 56.0 |

The materials used in Tables 4 to 6 are as follows.

(A) Colorant

Green Pigment Dispersion: Each of the Green Pigment Dispersions of Preparation Examples 1 to 11 and Preparation Comparative Examples 1 and 2

Yellow Pigment Dispersion

(B) Photopolymerizable Monomer

Dipentaerythritol hexaacrylate (DPHA, manufacturer: Nippon Kayaku Co., Ltd.)

(C) Photopolymerization Initiator

C-1: 1,2-octandione

C-2: 2-dimethylamino-2-(4-methyl-benzyl)-1-(4-morpholin-4-yl-phenyl)-butan-1-one

(D) Binder Resin

Resin copolymerized with 85:15 of benzyl methacrylate and methacrylic acid (Mw=22,000)

(E) Solvent

Propylene Glycol Monomethylether Acetate (PGMEA)

### Evaluation Example 1: Dispersibility and Dispersion Stability

A dynamic light scattering analysis equipment was used to measure a particle diameter of a solid included in each photosensitive resin composition of Examples 1 to 11 and Comparative Examples 1 and 2, and the results are shown in Table 7.

In addition, each photosensitive resin composition of Examples 1 to 11 and Comparative Examples 1 and 2 was evaluated with respect to viscosity by using a Brookfield DV-II Pro viscosity meter and CPE-52 Spindle at 5 rpm (rpm where Torque is 50 to 100%) at 25° C. before and after being stored at 23° C. for 1 week, and the results are shown in Table 7.

TABLE 7

| | Solid particle diameter (nm) | | | Viscosity (cPs) | | |
|---|---|---|---|---|---|---|
| | After | 1 week | | After | 1 week | |
| | preparation | later | Difference | preparation | later | Difference |
| Example 1 | 44.0 | 44.2 | 0.2 | 3.72 | 3.80 | 0.08 |
| Example 2 | 45.5 | 46.2 | 0.7 | 4.01 | 4.07 | 0.06 |
| Example 3 | 42.4 | 43.1 | 0.7 | 3.80 | 3.80 | 0.00 |
| Example 4 | 43.2 | 43.8 | 0.6 | 3.90 | 3.94 | 0.04 |
| Example 5 | 45.1 | 45.8 | 0.7 | 4.12 | 4.17 | 0.05 |
| Example 6 | 46.5 | 47.0 | 0.5 | 3.94 | 3.98 | 0.04 |
| Example 7 | 43.6 | 44.0 | 0.4 | 3.62 | 3.71 | 0.09 |
| Example 8 | 43.0 | 43.2 | 0.2 | 3.78 | 3.84 | 0.06 |
| Example 9 | 45.5 | 46.2 | 0.7 | 4.01 | 4.07 | 0.06 |
| Example 10 | 43.8 | 44.2 | 0.4 | 3.98 | 4.00 | 0.02 |
| Example 11 | 47.0 | 46.9 | −0.1 | 3.86 | 4.00 | 0.14 |
| Comparative | 43.4 | 46.7 | 3.3 | 4.78 | 6.02 | 1.24 |
| Example 1 | | | | | | |
| Comparative | 43.0 | 44.7 | 1.7 | 3.99 | 5.84 | 1.85 |
| Example 2 | | | | | | |

Referring to Table 7, the photosensitive resin compositions of Examples 1 to 11 exhibited a small difference in viscosity as well as a solid particle diameter before and after the storage for one week, compared with the photosensitive resin compositions of Comparative Examples 1 and 2.

### Evaluation Example 2: Coloring Power and Contrast Ratio

Each photosensitive resin composition of Examples 1 to 10 and Comparative Examples 1 and 2 was applied to be 1 to 3 m thick on a 1 mm-thick washed and degreased glass substrate and then, dried on a 90° C. hot plate for 2 minutes, obtaining a film. Subsequently, the film was exposed by using a high-pressure mercury lamp having a main wavelength of 365 nm and dried at 200° C. in a hot air circulation drier for 5 minutes, obtaining a color filter specimen.

As a pixel layer, a spectrophotometer (MCPD3000, Otsuka Electronics Co., Ltd.) was used to measure a color coordinate (x, y), luminance (Y), and a contrast ratio of each color filter specimen, and the results are shown in Tables 8 to 10.

TABLE 8

| | x | y | Y | Contrast ratio |
|---|---|---|---|---|
| Example 1 | 0.281 | 0.578 | 63.4 | 15,500 |
| Example 2 | 0.275 | 0.576 | 62.4 | 14,800 |
| Example 3 | 0.279 | 0.579 | 62.2 | 14,900 |
| Example 4 | 0.278 | 0.574 | 62.9 | 15,200 |
| Example 5 | 0.280 | 0.578 | 63.3 | 15,700 |
| Example 6 | 0.279 | 0.579 | 63.1 | 15,300 |

TABLE 9

| | x | y | Y | Contrast ratio |
|---|---|---|---|---|
| Example 7 | 0.278 | 0.574 | 62.9 | 15,200 |
| Example 8 | 0.280 | 0.578 | 63.3 | 15,700 |
| Example 3 | 0.279 | 0.579 | 62.2 | 14,900 |
| Example 9 | 0.274 | 0.575 | 62.8 | 15,200 |
| Example 10 | 0.281 | 0.579 | 63.5 | 15,600 |
| Example 11 | 0.282 | 0.578 | 62.9 | 15,200 |

TABLE 10

| | x | y | Y | Contrast ratio |
|---|---|---|---|---|
| Comparative Example 1 | 0.271 | 0.560 | 60.1 | 13,600 |
| Comparative Example 2 | 0.281 | 0.580 | 62.2 | 14,800 |

Referring to Tables 8 to 10, the color filter specimens of Examples 1 to 11 exhibited improved coloring power and contrast ratio, compared with the color filter specimens of Comparative Examples 1 and 2.

When a dispersing aid represented by Chemical Formula 1 was used, a photosensitive resin composition having high dispersibility and dispersion stability of a pigment and thus excellent coloring power and contrast ratio, when a color filter was formed, was obtained.

Examples 1 to 11 were representatively exemplified and may be adjusted within the scope of an embodiment to secure dispersibility, dispersion stability, coloring power, a contrast ratio, or the like to a desired level.

By way of summation and review, a photosensitive resin composition for a color filter for the pigment dispersion method may have improved performance as well as excellent pattern characteristics. In particular, a high color gamut and contrast ratio characteristics may be desirable.

One or more embodiments may provide a photosensitive resin composition having high dispersibility and dispersion stability, and excellent coloring power and contrast ratio when implementing a color filter.

The photosensitive resin composition according to an embodiment may have high dispersibility and dispersion stability, and may be excellent in coloring power and contrast ratio when implementing a color filter. Therefore, when using the photosensitive resin composition according to an embodiment, an excellent color filter and display device may be implemented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a colorant;
a photopolymerizable compound;
a photopolymerization initiator;
a binder resin; and
a solvent,
wherein:
the colorant includes a pigment, a dispersant, and a dispersing aid represented by Chemical Formula 1, 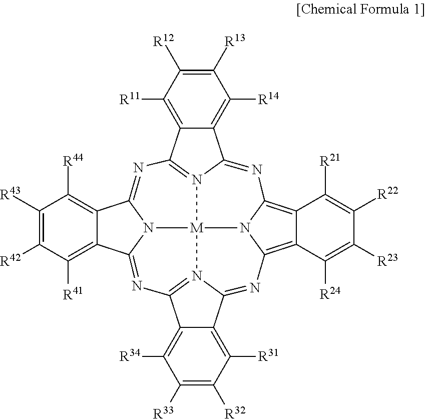
in Chemical Formula 1,
M is Cu or Zn;
R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group; and
R⁴¹ to R⁴⁴ are each independently a hydrogen atom, a halogen atom, a hydroxy group, a substituted or unsubstituted C1 to C20 alkyl group, or a substituted or unsubstituted C1 to C20 alkoxy group, provided that at least one of R⁴¹ to R⁴⁴ is a C1 to C20 alkoxy group substituted with a sulfonate group.

2. The photosensitive resin composition as claimed in claim 1, wherein R¹¹ to R¹⁴ are all hydrogen atoms or all halogen atoms.

3. The photosensitive resin composition as claimed in claim 1, wherein one of R²¹ to R²⁴ is a substituted or unsubstituted C1 to C20 alkyl group.

4. The photosensitive resin composition as claimed in claim 1, wherein R³¹ to R³⁴ are all hydrogen atoms.

5. The photosensitive resin composition as claimed in claim 1, wherein:
one of R⁴¹ to R⁴⁴ is a moiety represented by *—O-L¹-L²-A;
L¹ is a single bond or a substituted or unsubstituted C6 to C20 arylene group;
L² is a single bond or a substituted or unsubstituted C1 to C20 alkylene group; and
A is an anion of SO₃⁻ alone, or a salt of a combination of SO₃⁻ and Na⁺.

6. The photosensitive resin composition as claimed in claim 5, wherein L¹ is a single bond or a substituted or unsubstituted phenylene group.

7. The photosensitive resin composition as claimed in claim 5, wherein L² is a substituted or unsubstituted C1 to C10 alkylene group.

8. The photosensitive resin composition as claimed in claim 5, wherein A is a salt of a combination of SO₃⁻ and Na⁺.

9. The photosensitive resin composition as claimed in claim 5, wherein:
the moiety represented by *—O-L¹-L²-A is represented by Chemical Formula 2 or Chemical Formula 3, 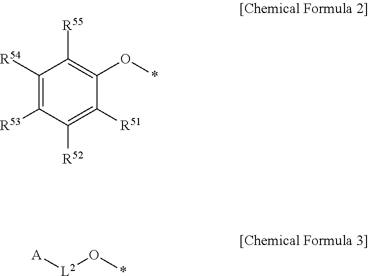
in Chemical Formulae 2 and 3,
R⁵¹ to R⁵⁵ are each independently a hydrogen atom, a halogen atom, a hydroxyl group, a substituted or unsubstituted C1 to C20 alkyl group, or a moiety represented by *-L²-A, at least one of R⁵¹ to R⁵⁵ being a moiety represented by *-L²-A;
L² is a substituted or unsubstituted C1 to C20 alkylene group; and
A is an anion of SO₃⁻ alone, or a salt of a combination of SO₃⁻ and Na⁺.

10. The photosensitive resin composition as claimed in claim 1, wherein:
the dispersing aid represented by Chemical Formula 1 is represented by one of Chemical Formulae 1-1 to 1-4: 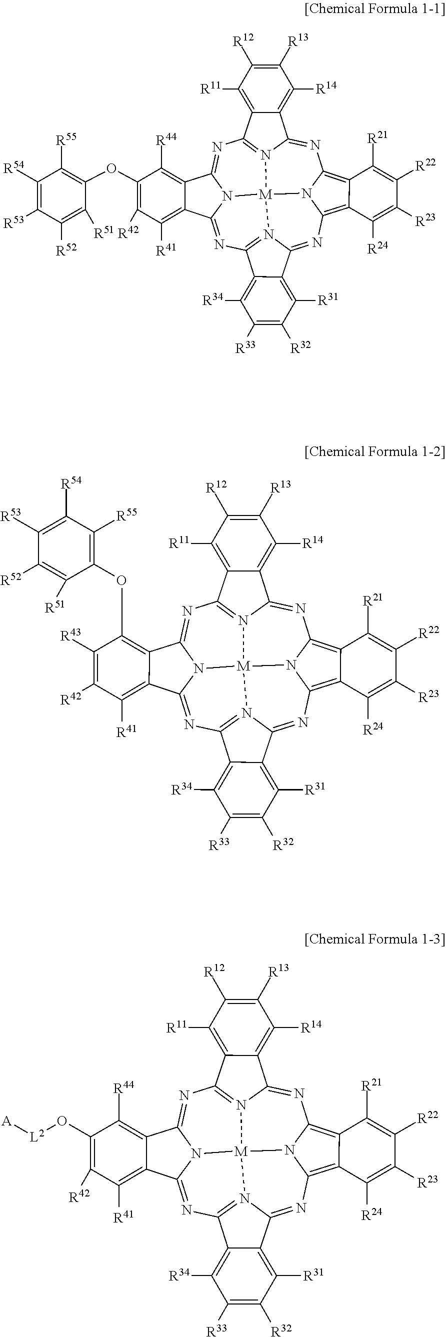 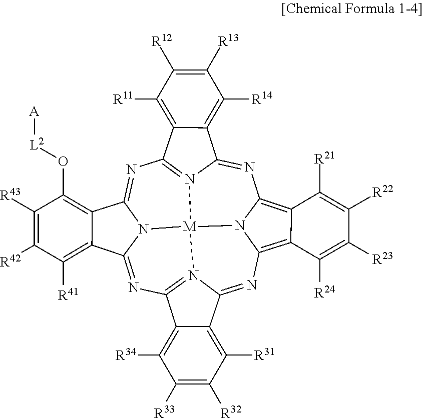
in Chemical Formulas 1-1 to 1-4,
M is Cu or Zn;
R¹¹ to R¹⁴, R²¹ to R²⁴, R³¹ to R³⁴, and R⁴¹ to R⁴⁴ are each independently a hydrogen atom, a halogen atom, a hydroxy group, or a substituted or unsubstituted C1 to C20 alkyl group;
R⁵¹ to R⁵⁵ are each independently a hydrogen atom, a halogen atom, a hydroxyl group, a substituted or unsubstituted C1 to C20 alkyl group, or a moiety represented by *-L²-A, at least one of R⁵¹ to R⁵⁵ being a moiety represented by *-L²-A;
L² is a substituted or unsubstituted C1 to C20 alkylene group; and
A is an anion of SO₃⁻ alone, or a salt of a combination of SO₃⁻ and Na⁺.

11. The photosensitive resin composition as claimed in claim 1, wherein the dispersing aid represented by Chemical Formula 1 is one of the following compounds:

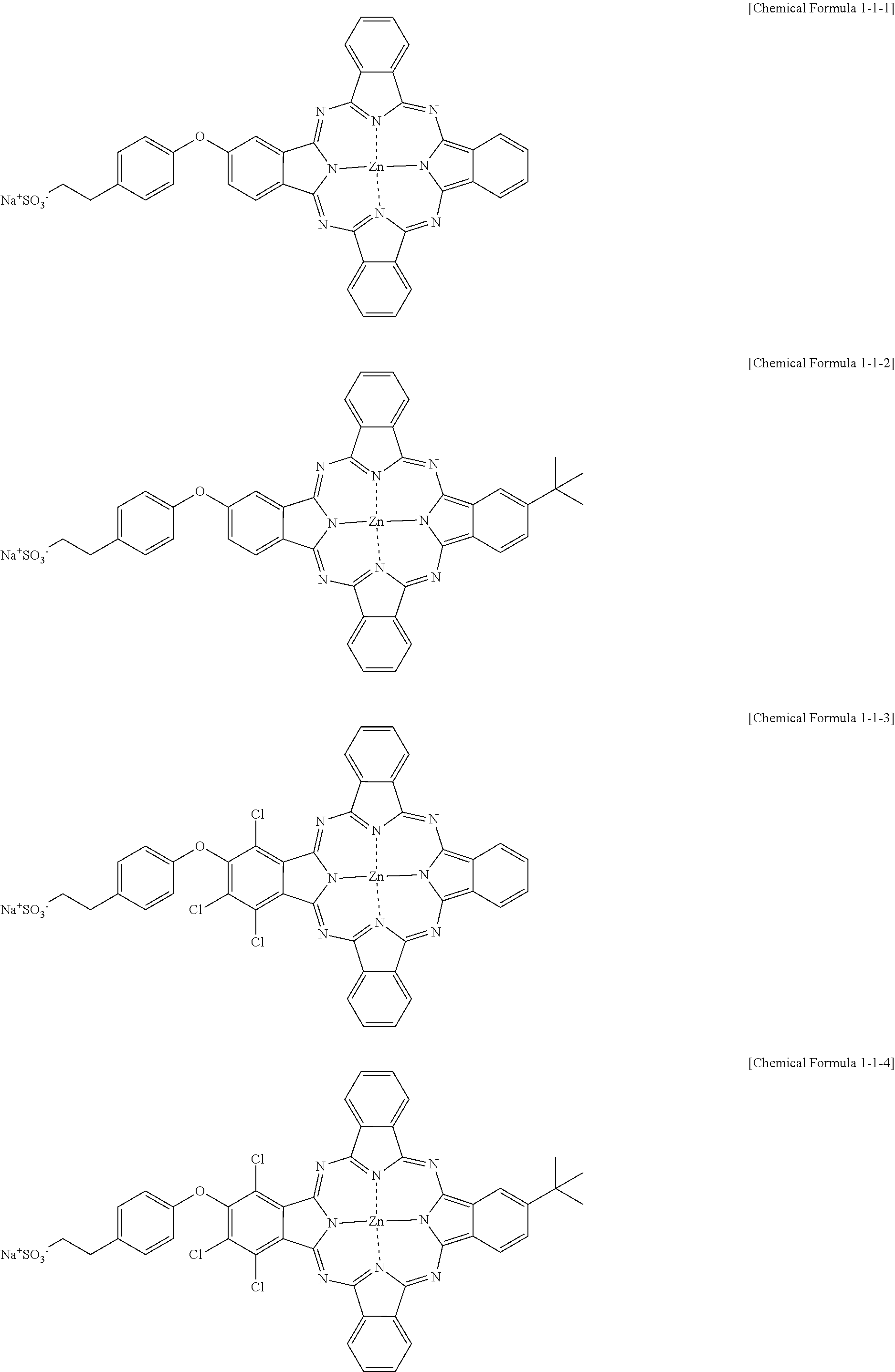

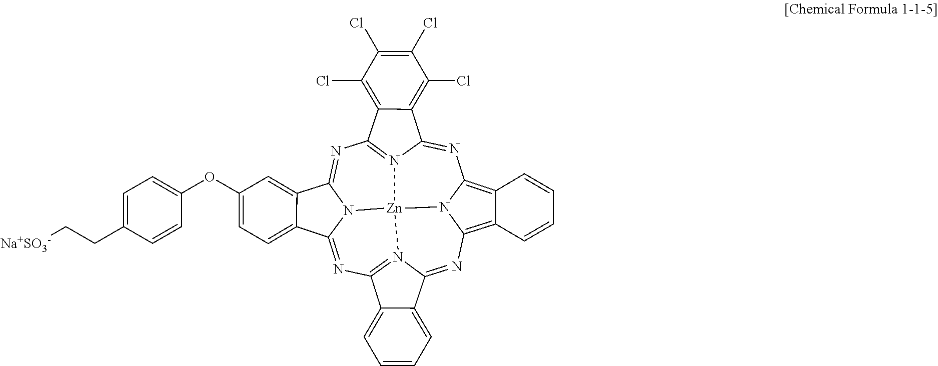

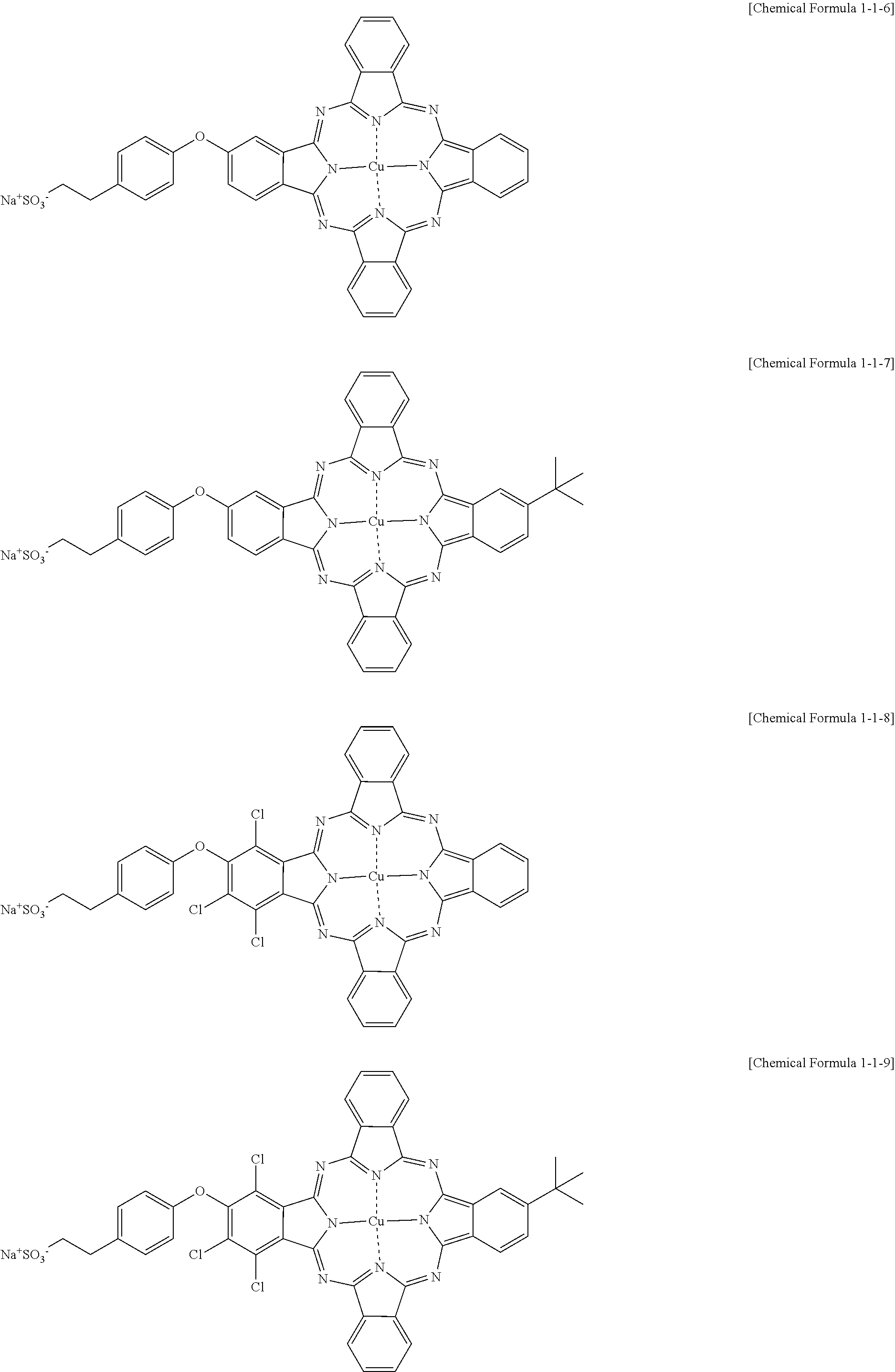

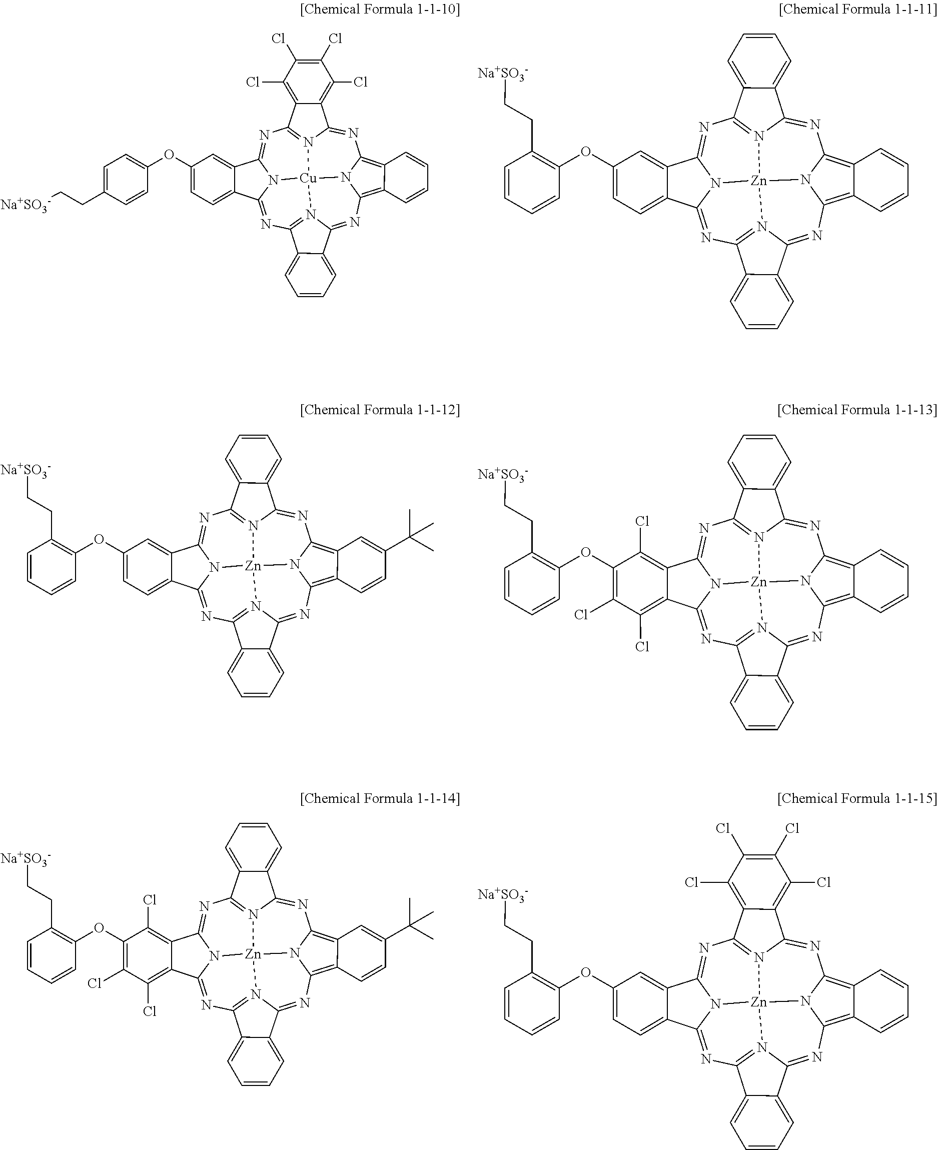

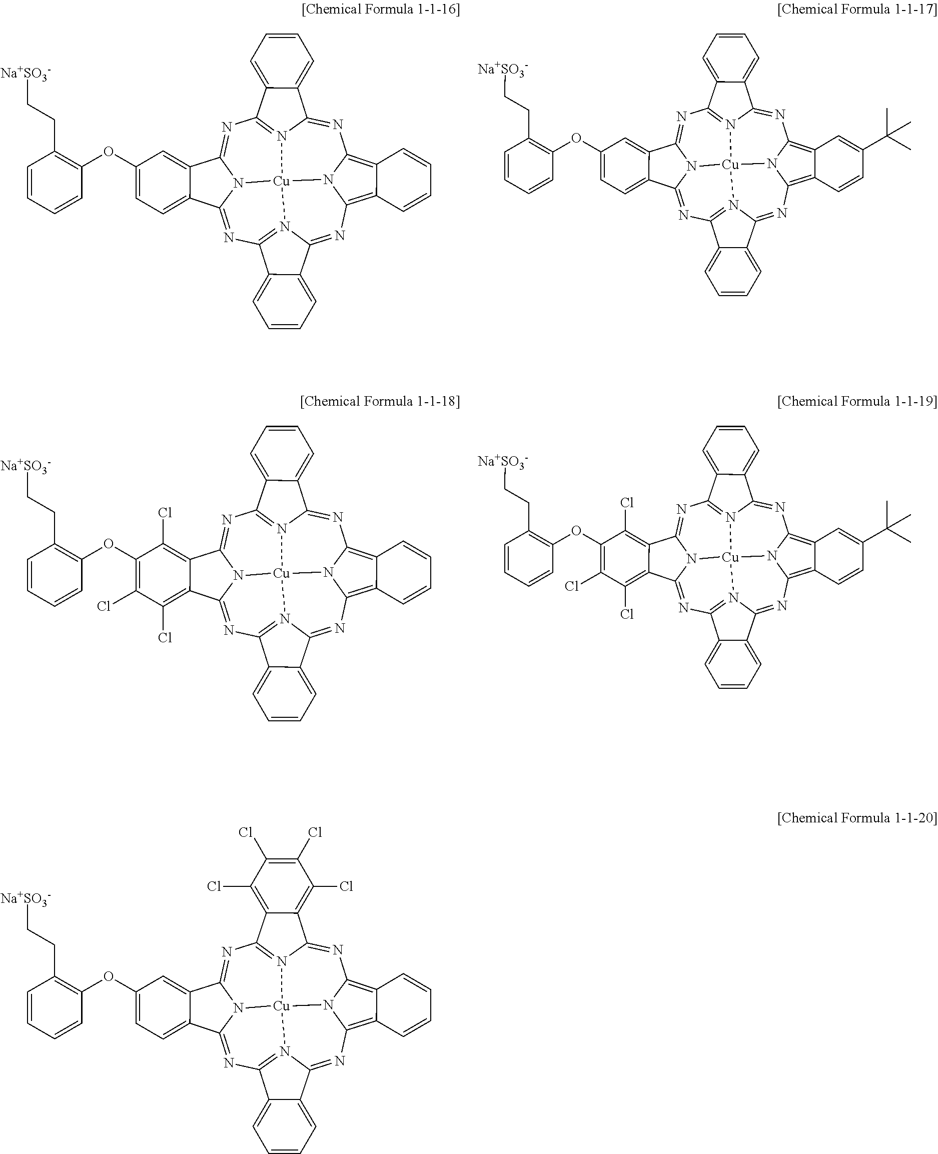

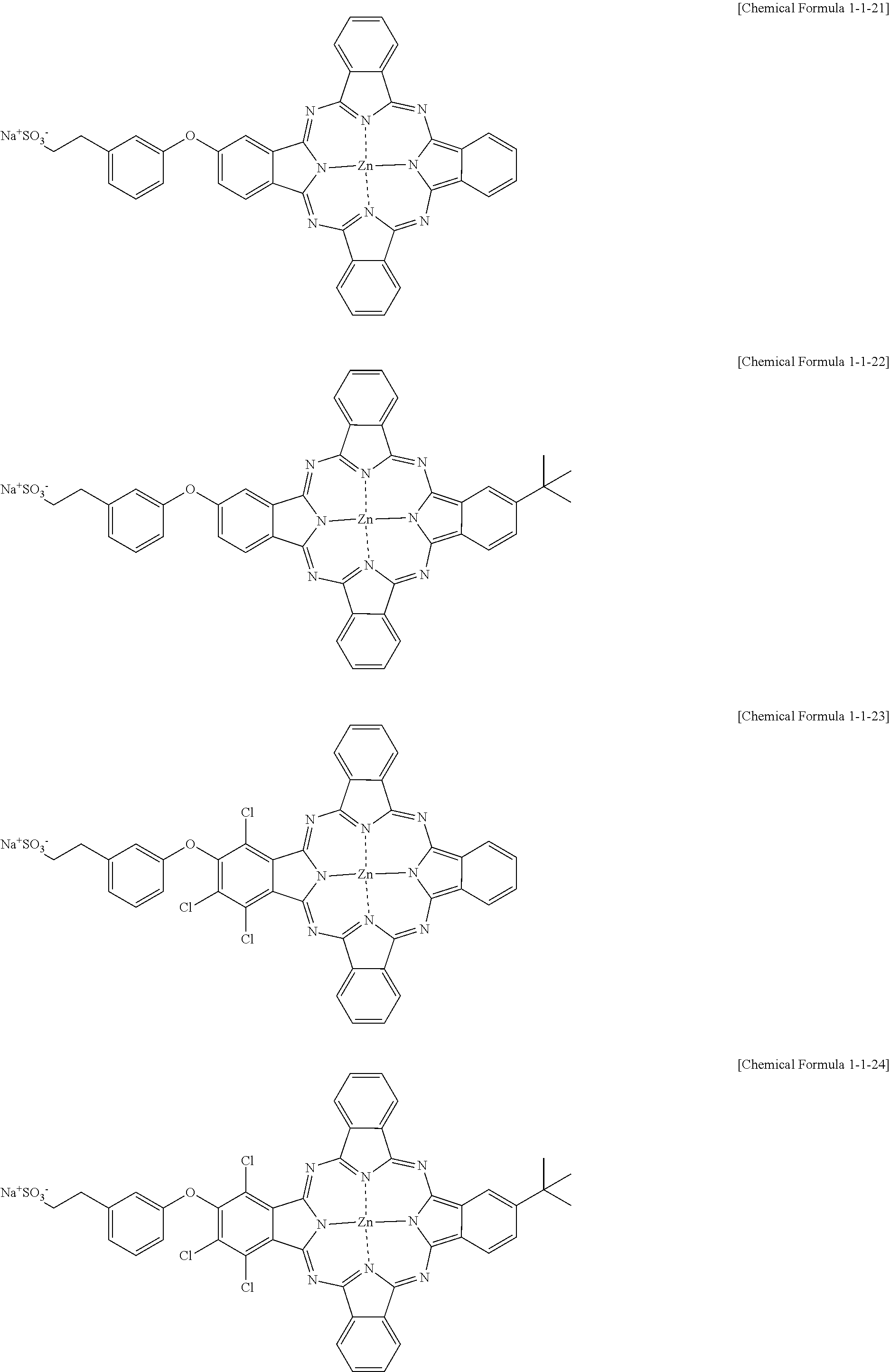

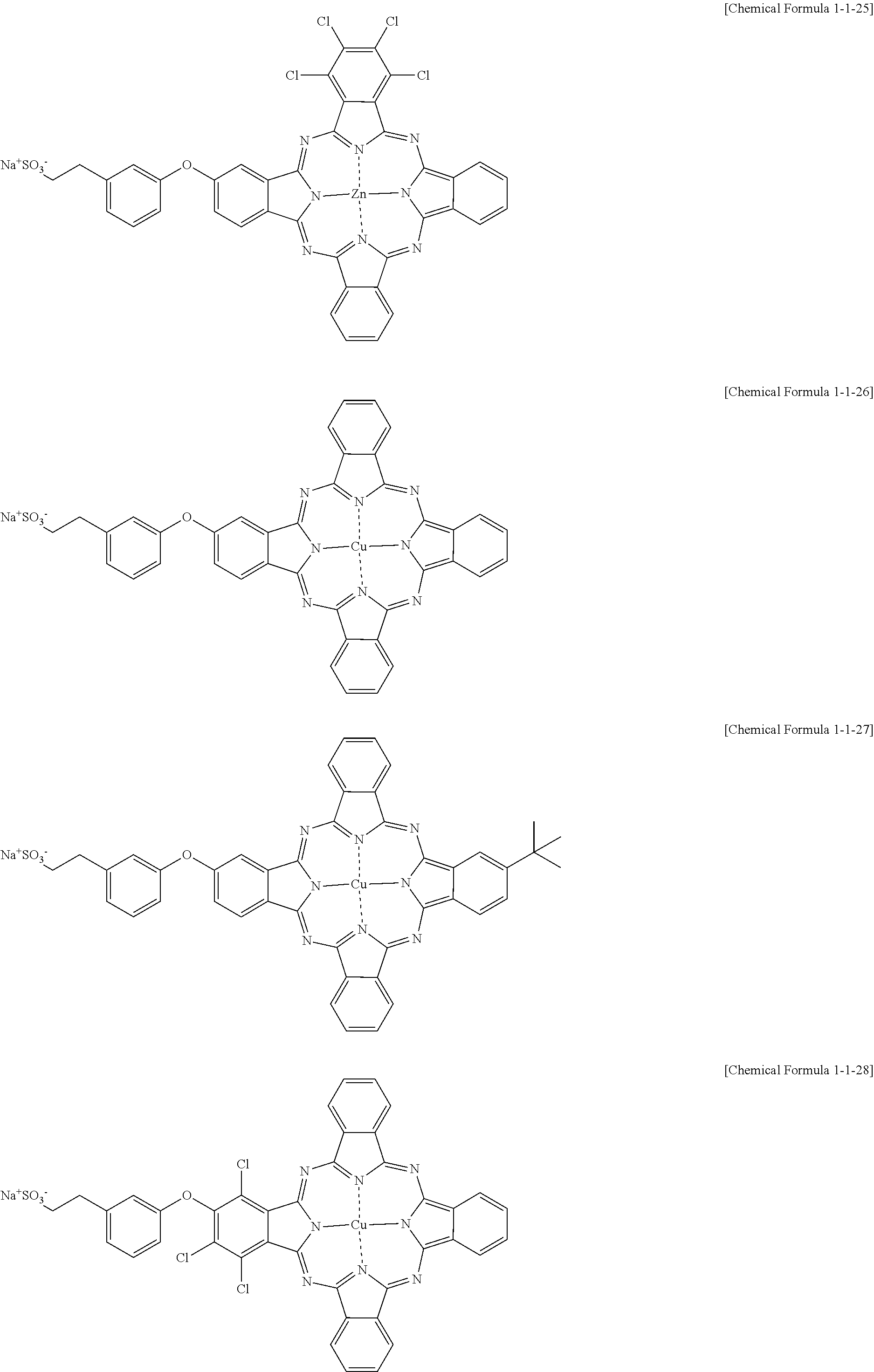

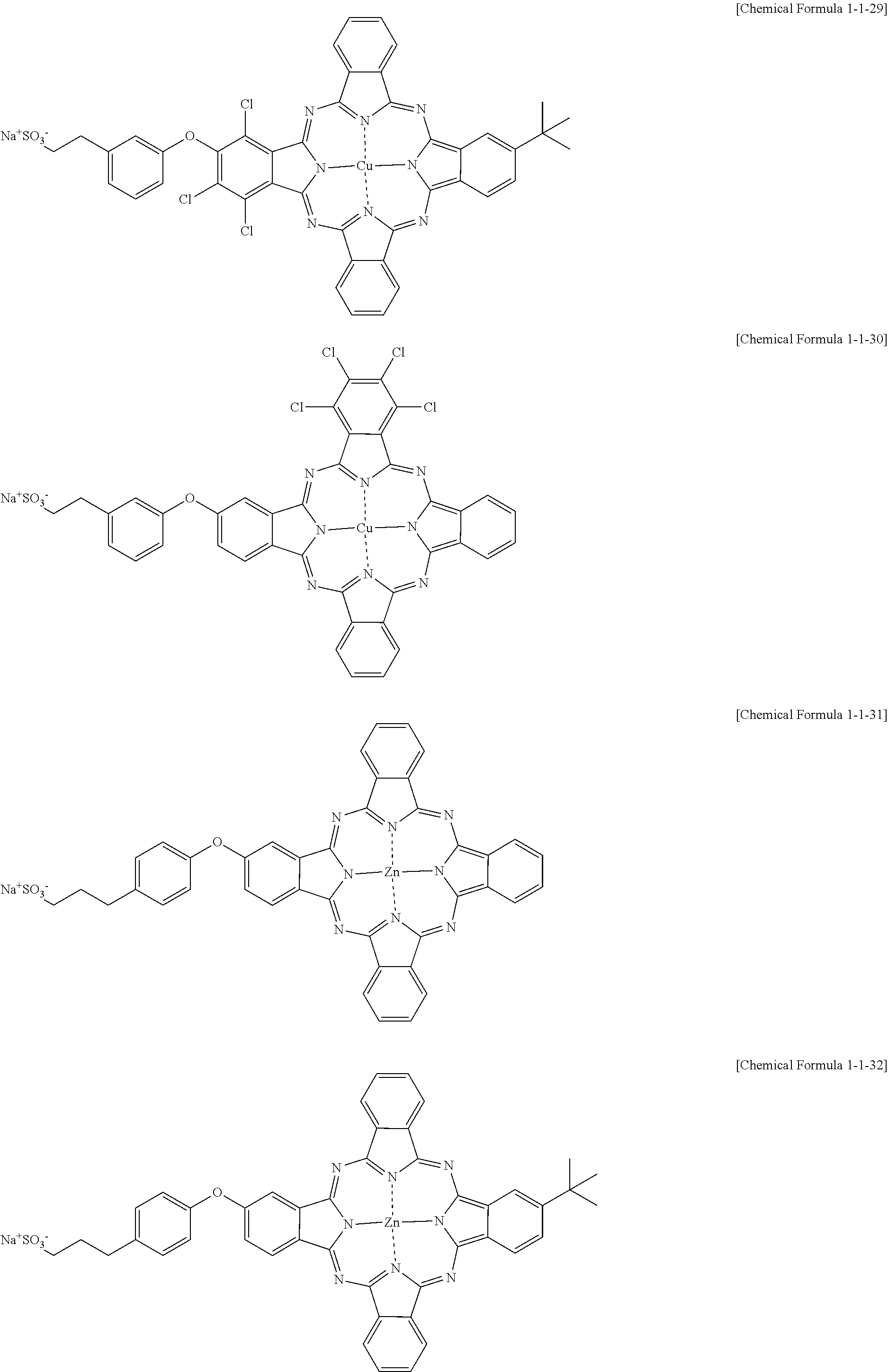

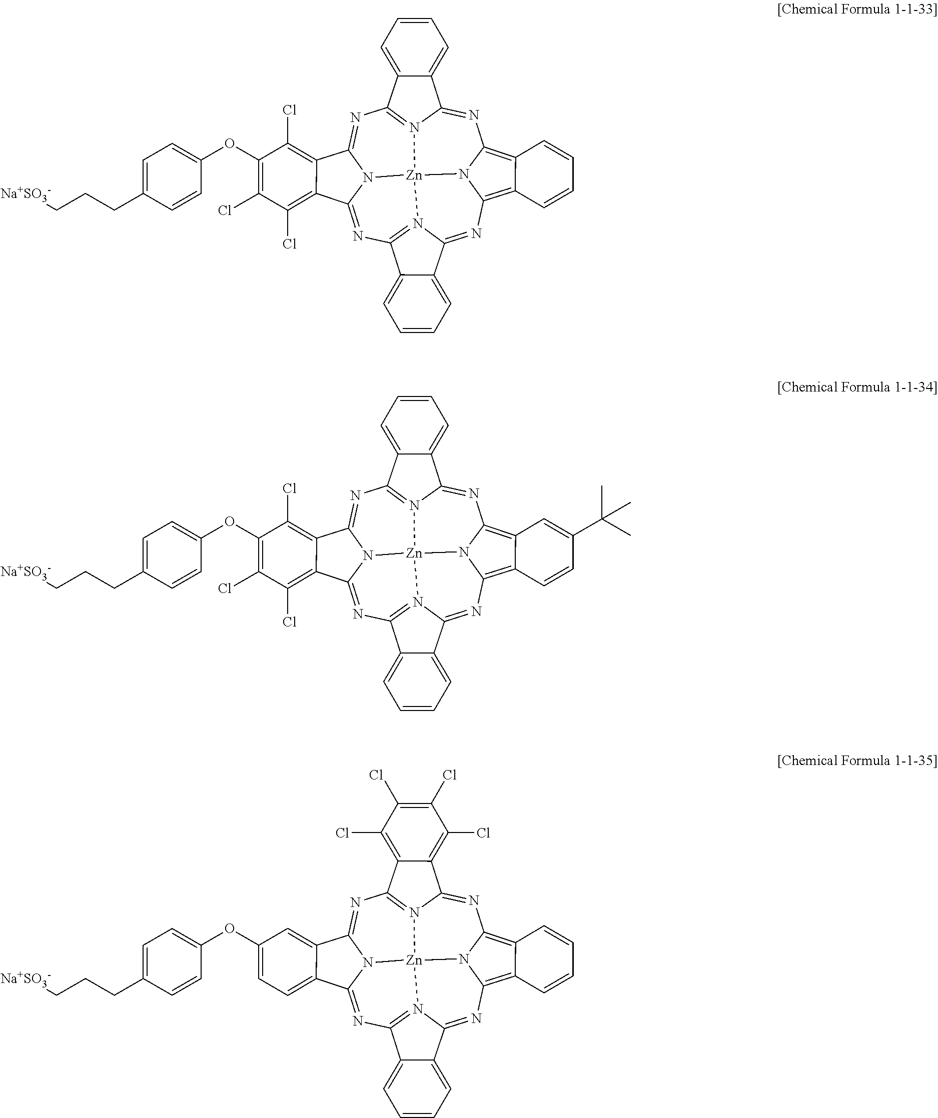

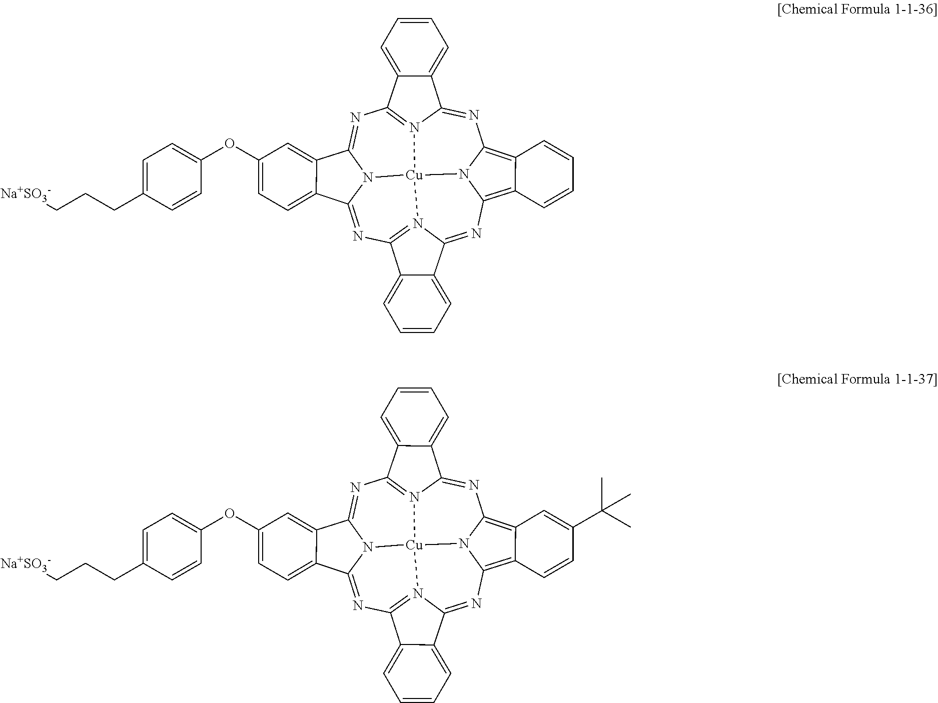

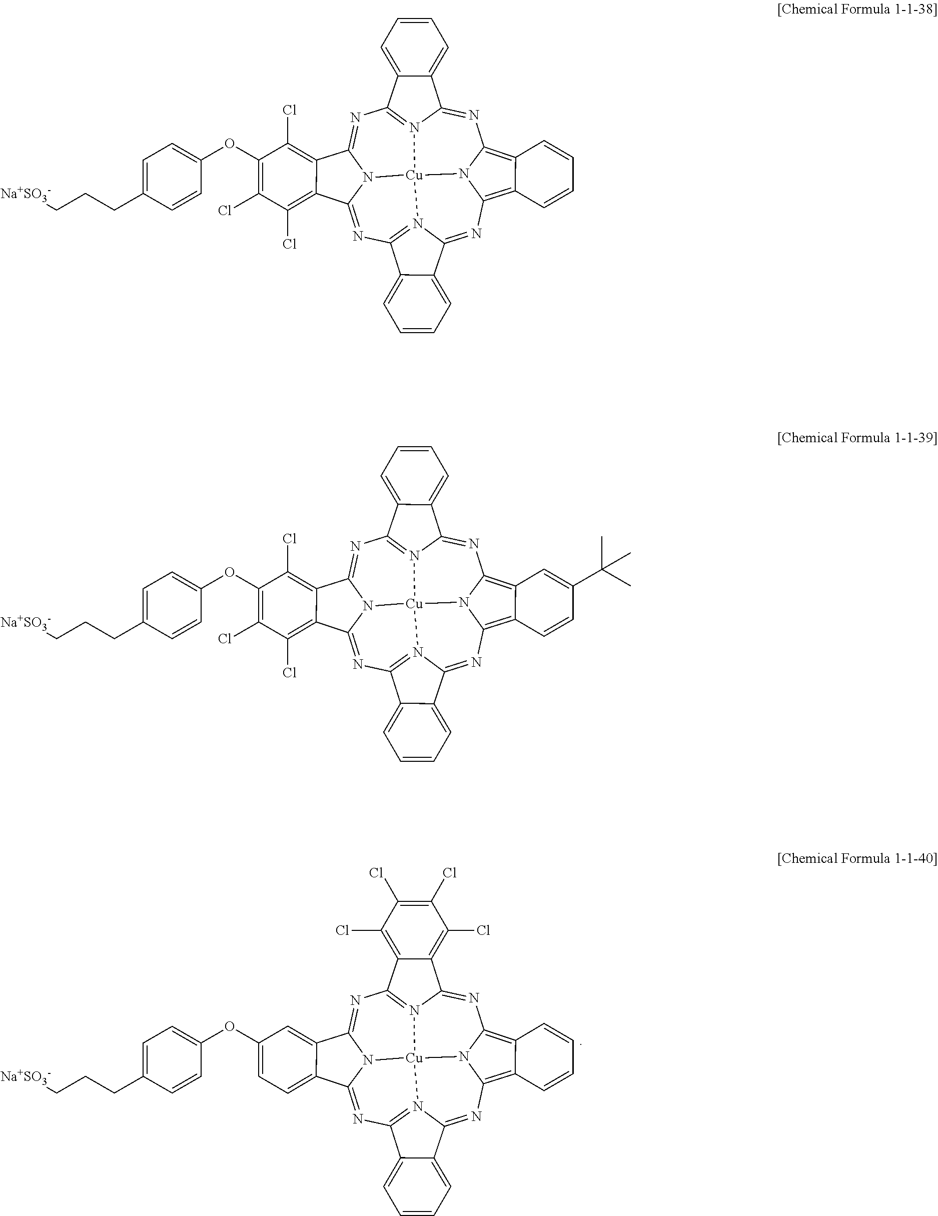

12. The photosensitive resin composition as claimed in claim 1, wherein the dispersing aid represented by Chemical Formula 1 has a maximum absorption wavelength of about 450 nm to about 495 nm.

13. The photosensitive resin composition as claimed in claim 1, wherein the dispersing aid represented by Chemical Formula 1 is included in an amount of about 0.5 wt % to about 6 wt %, based on a total weight of the photosensitive resin composition.

14. The photosensitive resin composition as claimed in claim 1, wherein a weight ratio of the dispersing aid represented by Chemical Formula 1 and the pigment is about 1:20 to about 1:70.

15. The photosensitive resin composition as claimed in claim 1, wherein the pigment includes a green pigment, a yellow pigment, or a combination thereof.

16. The photosensitive resin composition as claimed in claim 1, wherein the photosensitive resin composition includes:
about 0.5 wt % to about 15 wt % of the colorant;
about 0.1 wt % to about 10 wt % of the photopolymerizable compound;
about 0.1 wt % to about 10 wt % of the photopolymerization initiator;
about 0.5 wt % to about 15 wt % of the binder resin; and
the solvent, all wt % being based on a total weight of the photosensitive resin composition.

17. A photosensitive resin layer manufactured using the photosensitive resin composition as claimed in claim 1.

18. The photosensitive resin layer as claimed in claim 17, wherein the photosensitive resin layer is a color negative photoresist.

19. A color filter comprising the photosensitive resin layer as claimed in claim 17.

20. A display device comprising the color filter of claim 19.
